(19) United States
(12) Patent Application Publication
(10) Pub. No.: US 2013/0314147 A1
(43) Pub. Date: Nov. 28, 2013

(54) SEMICONDUCTOR PROCESSING DEVICE AND SEMICONDUCTOR PROCESSING SYSTEM

(71) Applicants: Nobuo Shimizu, Itami-shi (JP); Yutaka Takikawa, Itami-shi (JP)

(72) Inventors: Nobuo Shimizu, Itami-shi (JP); Yutaka Takikawa, Itami-shi (JP)

(21) Appl. No.: 13/984,875

(22) PCT Filed: Mar. 28, 2012
(86) PCT No.: PCT/JP2012/058110

§ 371 Date: Aug. 12, 2013

(30) Foreign Application Priority Data
Mar. 28, 2011 (JP) 2011-069785

(51) Int. Cl. H03M 1/66

(52) U.S. Cl. CPC H03M 1/66
USPC 327/437; 327/419

(57) ABSTRACT

A semiconductor processing device (10) of the present invention includes a processing circuit (1), a digital-analog conversion circuit (2), an output control circuit (3), at least one output port circuit (4), a connection control circuit (5), and an output switch circuit (6). The output port circuit (4) includes an output buffer (41), a first switch element (SW1), and a second switch element (SW2, SW3). When the second switch element is connected to the side of an output amplifier (42), the output port circuit (4) controls the ON resistance of a P channel MOS transistor (41a) and an N channel MOS transistor (41b) based on a signal amplified at the output amplifier (42) to output an analog signal from the output buffer (41).

### TECHNICAL FIELD

The present invention relates to a semiconductor processing device and a semiconductor processing system, particularly a semiconductor processing device including a digital-analog conversion circuit, and a semiconductor processing system.

### BACKGROUND ART

In recent years, a semiconductor processing device such as a microcontroller and SoC (System on a Chip) is required to output, not only a digital signal, but also an analog signal. In the case where a semiconductor processing device is to output an analog signal, the semiconductor processing device required a digital-analog conversion circuit and an output port circuit to output an analog signal. For example, the semiconductor processing device disclosed in Japanese Patent Laying-Open No. 2010-45553 (PTD 1) includes a digital-analog conversion circuit converting a digital signal output from a microprocessor into an analog signal, a plurality of output port circuits, and a multiplexer switching the connection between the digital-analog conversion circuit and the plurality of output port circuits.

The semiconductor processing device disclosed in Patent Document 1 also includes a reference circuit to determine whether the voltage of an analog signal output from an output port circuit is within an appropriate range, and a comparator comparing the voltage of an analog signal output from the output port circuit with the voltage of an analog signal output from the reference circuit.

### CITATION LIST

### Patent Document

PTD 1: Japanese Patent Laying-Open No. 2010-45553

### SUMMARY OF INVENTION

### Technical Problem

The semiconductor processing device disclosed in PTD 1 is disadvantageous in that the number of output port circuits is increased since the output port circuit providing a digital signal and the output port circuit providing an analog signal are arranged independent of each other. Particularly, in order to down-size the semiconductor processing device, the number of output port circuits must be reduced. There is a need to output an analog signal from an output port circuit providing a digital signal output by using in common an output port circuit providing a digital signal output and an output port circuit providing an analog signal output.

Furthermore, in the case where an analog signal is to be output from one digital-analog conversion circuit to a plurality of output port circuits, it was difficult to align each impedance of a circuit (for example, a memory circuit, sensor circuit, and the like) connected to each output port circuit with the impedance of the digital-analog conversion circuit. Therefore, a conventional semiconductor processing device had the problem that the configuration in which one output port circuit is provided for one digital-analog conversion circuit is restricted.

Moreover, in the case where an analog signal of a different voltage is to be output from the plurality of output port circuits, the conventional semiconductor processing device is restricted to a configuration in which a digital-analog conversion circuit had to be provided corresponding to the number of different level of voltages. Thus, there was a problem that the semiconductor processing device could not be reduced in size.

In view of the foregoing, an object of the present invention is to provide a semiconductor processing device having an analog signal output from an output port circuit that outputs a digital signal, allowing an output port circuit providing a digital signal output and an output port circuit providing an analog signal output to be used in common, and a semiconductor processing system. Another object of the present invention is to provide a semiconductor processing device including a plurality of output port circuits for one digital-analog conversion circuit, allowing an analog signal of a different voltage to be output from a relevant output port circuit and a semiconductor processing system.

### Solution to Problem

In view of the foregoing, the present invention is directed to including a digital-analog conversion circuit generating a reference voltage, and, for every output port circuit, a reference voltage storing circuit and a comparison circuit comparing an output analog voltage with a reference voltage. The output port circuit is controlled such that the output analog voltage matches the reference voltage.

### Advantageous Effects of Invention

By the configuration set forth above, a digital-analog conversion circuit generating a reference voltage can be used in common.

More specifically, according to a semiconductor processing device of the present invention, ON resistance of a transistor circuit of an output buffer providing a digital signal output is controlled to cause an analog signal to be output from the output buffer. Therefore, an analog signal can be output from an output port circuit providing a digital signal output. Thus, an output port providing a digital signal output and an output port circuit providing an analog signal output can be used in common in the semiconductor processing device, allowing the number of output port circuits to be reduced for down-sizing. Since the semiconductor processing device of the present invention allows an analog signal output from the digital-analog conversion circuit to be output from an output port circuit using an output buffer, it is not necessary to align the impedance of a circuit connected to the output port circuit with the impedance of the digital-analog conversion circuit. A configuration in which a plurality of output port circuits are provided for one digital-analog conversion circuit can be achieved.

Since the ON resistance of a transistor circuit in an output buffer is controlled for every output port circuit to output an analog signal according to the semiconductor processing device of the present invention, an analog signal of a different voltage can be output from the output buffer of each output port circuit. Moreover, a semiconductor processing system of the present invention includes a semiconductor processing device that can output an analog signal of a different voltage from an output buffer of each of a plurality of output port circuits. Therefore, a circuit driven by an analog signal of a different voltage can be connected to the semiconductor processing device without having to provide a plurality of digital-analog conversion circuits, voltage conversion circuits, and the like. Thus, the semiconductor processing system can be down-sized.

### BRIEF DESCRIPTION OF DRAWINGS

FIG. 1 is a schematic diagram representing a configuration of a semiconductor processing device according to a first embodiment of the present invention.

FIG. 2 is a flowchart to describe an operation of the semiconductor processing device according to the first embodiment of the present invention.

FIG. 3 is a schematic diagram representing a configuration of a semiconductor processing device according to a second embodiment of the present invention.

FIG. 4 is a schematic diagram representing a configuration of a connection control circuit of a semiconductor processing device according to a third embodiment of the present invention.

FIG. 5 is a flowchart to describe an operation of the semiconductor processing device according to the third embodiment of the present invention.

FIG. 6 is a schematic diagram representing a configuration of a semiconductor processing system according to a fourth embodiment of the present invention.

FIG. 7 is a schematic diagram representing a configuration of a semiconductor processing device according to a fifth embodiment of the present invention.

FIG. 8 is a flowchart to describe an operation of the semiconductor processing device according to the fifth embodiment of the present invention.

FIG. 9 is a schematic diagram representing a configuration of a semiconductor processing device according to a sixth embodiment of the present invention.

FIG. 10 is a flowchart to describe an operation of the semiconductor processing device according to the sixth embodiment of the present invention.

FIG. 11 is a schematic diagram representing a configuration of a semiconductor processing device according to a seventh embodiment of the present invention.

FIG. 12 is a flowchart to describe an operation of the semiconductor processing device according to the seventh embodiment of the present invention.

FIG. 13 is a flowchart to describe an operation of processing A of the semiconductor processing device according to the seventh embodiment of the present invention.

FIG. 14 is a schematic diagram representing a configuration of a semiconductor processing device according to an eighth embodiment of the present invention.

FIG. 15 is a flowchart to describe an operation of the semiconductor processing device according to the eighth embodiment of the present invention.

FIG. 16 is a schematic diagram representing a configuration of a semiconductor processing device according to a ninth embodiment of the present invention.

FIG. 17 is a flowchart to describe an operation of the semiconductor processing device according to the ninth embodiment of the present invention.

FIG. 18 is a flowchart to describe an operation of processing C of the semiconductor processing device according to the ninth embodiment of the present invention.

### DESCRIPTION OF EMBODIMENTS

Embodiments of the present invention will be described hereinafter with reference to the drawings.

(First Embodiment)

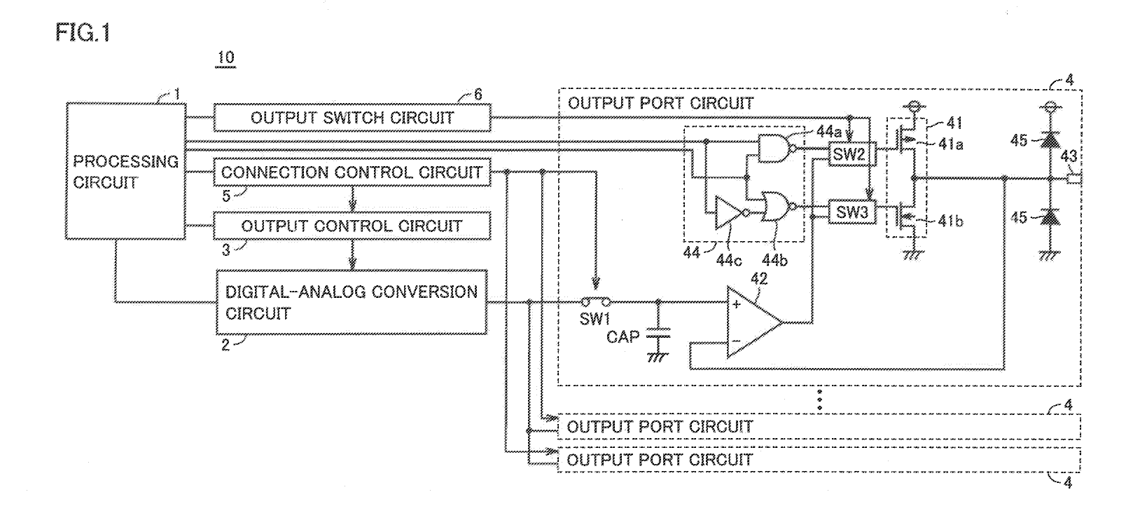

FIG. 1 is a schematic diagram representing a configuration of a semiconductor processing device according to a first embodiment of the present invention. A semiconductor processing device 10 shown in FIG. 1 includes a processing circuit 1, a digital-analog conversion circuit 2, an output control circuit 3, a plurality of output port circuits 4, a connection control circuit 5, and an output switch circuit 6. The configuration is not limited to a plurality of output port circuits 4 connected to one digital-analog conversion circuit. A configuration in which one output port circuit 4 is connected to one digital-analog conversion circuit 2 may be implemented.

Processing circuit 1 is a CPU, a MPU, or the like, performing a desired operational process based on an input signal to output a digital signal such as a control signal to a circuit such as digital-analog conversion circuit 2 and output control circuit 3. Digital-analog conversion circuit 2 converts a digital signal output from processing circuit 1 into an analog signal. Output control circuit 3 controls the output of an analog signal converted by digital-analog conversion circuit 2. For example, output control circuit 3 sets in advance the desired voltage of an analog signal to be output from digital-analog conversion circuit 2, and instructs digital-analog conversion circuit 2 to output an analog signal converted at digital-analog conversion circuit 2.

Output port circuit 4 outputs to an external source a digital signal output from processing circuit 1, or an analog signal output from digital-analog conversion circuit 2. Specifically, output port circuit 4 includes an output buffer 41, an output amplifier 42, a first switch element SW1, and second switch elements SW2, SW3. FIG. 1 depicts in detail the configuration of one output port circuit. Since the configuration of other output port circuit 4 is similar, detailed illustration thereof is not repeated.

Output buffer 41 is a CMOS circuit having a P channel MOS transistor 41a and an N channel MOS transistor 41b connected in series. P channel MOS transistor 41a has one end connected to a power supply, and the other end connected to N channel MOS transistor 41b. N channel MOS transistor 41b has one end connected to ground, and the other end connected to P channel MOS transistor 41a. Since output buffer 41 is constituted of a CMOS circuit generally employed in an output port circuit 4 providing a digital signal output, a particular circuit does not have to be employed. Therefore, fabrication is economical.

Output buffer 41 outputs a digital signal by switching between an ON state and an OFF state of P channel MOS transistor 41a and N channel MOS transistor 41b. Specifically, output buffer 41 does not output a digital signal provided from processing circuit 1 directly from output port 43, and converts a digital signal output from processing circuit 1 into a control signal at a logic circuit 44. Output buffer 41 outputs a digital signal by switching between the ON state and OFF state of P channel MOS transistor 41a and N channel MOS transistor 41b based on the converted control signal.

For example, when P channel MOS transistor 41a attains an ON state and N channel MOS transistor 41b attains an OFF state by supplying 2.8 V as the power supply voltage and 0 V as the ground voltage, output buffer 41 outputs a digital signal of an H level (2.8 V−threshold voltage). In the case where P channel MOS transistor 41a attains an OFF state and N channel MOS transistor 41b attains an ON state, output buffer 41 outputs a digital signal of an L level (0 V+threshold voltage). Logic circuit 44 includes a NAND circuit 44a connected to a gate terminal of P channel MOS transistor 41a, a NOR circuit 44b connected to a gate terminal of N channel MOS transistor 41b, and a NOT circuit 44c connected to one input terminal of NOR circuit 44b. Output buffer 41 is not limited to a CMOS circuit, and may be any transistor circuit including at least one transistor as long as a digital signal can be output by switching between an ON state and OFF state at the transistor. For example, output buffer 41 may be an open-drain output circuit including an N channel MOS transistor.

Output amplifier 42 amplifies an analog signal output from digital-analog conversion circuit 2. First switch element SW1 is provided between digital-analog conversion circuit 2 and output amplifier 42 to switch between connection and disconnection of digital-analog conversion circuit 2 and output amplifier 42, based on a control signal output from connection control circuit 5. Second switch elements SW2, SW3 are connected to the gate terminals of P channel MOS transistor 41a and N channel MOS transistor 41b, switching the connection between the side of processing circuit 1 and the side of output amplifier 42 based on a switch signal output from output switch circuit 6.

Output port circuit 4 has digital-analog conversion circuit 2 connected with output amplifier 42 when first switch element SW1 attains an ON state to provide an analog signal output from digital-analog conversion circuit 2 to output amplifier 42. When second switch elements SW2, SW3 are connected to the side of output amplifier 42 (when output buffer 41 and output amplifier 42 are connected) in output port circuit 4, the analog signal amplified at output amplifier 42 is applied to the gate terminals of P channel MOS transistor 41a and N channel MOS transistor 41b. Then, output port circuit 4 controls the ON resistance of P channel MOS transistor 41a and N channel MOS transistor 41b. By controlling the ON resistance of P channel MOS transistor 41a and N channel MOS transistor 41b, output port circuit 4 can provide from output buffer 41 an analog signal having a voltage in the range between the voltage (2.8 V) supplied as the power supply voltage and the ground voltage (0 V), taking into account the threshold voltage of each MOS transistor. When second switch elements SW2, SW3 are connected to the side of processing circuit 1 (when output buffer 41 and logic circuit 44 are connected), output port circuit 4 can output a digital signal from output buffer 41.

Output port circuit 4 includes an output port 43 providing a digital signal or analog signal output from output buffer 41 to an external source. In order to prevent damage of output port circuit 4 by input of an external signal to output port 43, a protection diode 45 is connected between output buffer 41 and output port 43.

Furthermore, output port circuit 4 has output amplifier 42 formed of an operational amplifier, applying an analog signal output from digital-analog conversion circuit 2 to the input terminal of the positive side and an analog signal output from output buffer 41 to the input terminal of the negative side. Accordingly, feedback control can be performed, allowing output amplifier 42 to modify the amplification factor of an analog signal based on a comparison result between the voltage of an analog signal output from output buffer 41 and the voltage of an analog signal output from digital-analog conversion circuit 2, such that the analog signal output from output buffer 41 matches the analog signal output from digital-analog conversion circuit 2.

It is to be noted that the semiconductor processing device disclosed in PTD 1 carries out feedback control by comparing the voltage of an analog signal output from an output port circuit with the voltage of an analog signal output from the reference circuit by means of a comparator. An error at the digital-analog conversion circuit generated in an analog signal output from the output port circuit overlaps with an error at the digital-analog conversion circuit generated in an analog signal output from the reference circuit, preventing feedback control of high accuracy. In contrast, semiconductor processing device 10 according to the first embodiment of the present invention can use the voltage of an analog signal output from digital-analog conversion circuit 2 instead of an analog signal output from the reference circuit. Therefore, the digital signal does not have to be converted again into an analog signal at digital-analog conversion circuit 2 in order to output an analog signal from the reference circuit. The error at digital-analog conversion circuit 2 generated in an analog signal output from the reference circuit can be reduced. Thus, semiconductor processing device 10 can carry out feedback control of high accuracy such that the analog signal output from output buffer 41 matches the analog signal output from digital-analog conversion circuit 2.

Output port circuit 4 includes a capacitor CAP storing the voltage of an analog signal output from digital-analog conversion circuit 2 when connection is established between digital-analog conversion circuit 2 and output amplifier 42 by first switch circuit SW1. Since output port circuit 4 has a capacitor CAP, there is no need to connect digital-analog conversion circuit 2 and output buffer 41 when output amplifier 42 compares the voltage of an analog signal output from output buffer 41 with the voltage of an analog signal output from digital-analog conversion circuit 2. In other words, feedback control can be performed by output amplifier 42 comparing the voltage of an analog signal output from output buffer 41 with the voltage of an analog signal output from digital-analog conversion circuit 2 that is stored in capacitor CAP. Therefore, semiconductor processing device 10 can cut the connection between digital-analog conversion circuit 2 and output amplifier 42 before the feedback control of one output port circuit 4 ends, and output an analog signal from the next output port circuit 4. Furthermore, since digital-analog conversion circuit 2 is disconnected from output amplifier 42 when feedback control is performed at output amplifier 42, the feedback control can be performed impervious to any variation in the voltage of an analog signal output from digital-analog conversion circuit. Since the voltage of the analog signal stored in capacitor CAP may vary due to leakage current or some other cause, the voltage of an analog signal output from digital-analog conversion circuit 2 is to be restored at a predetermined cycle.

Connection control circuit 5 controls the connection between digital-analog conversion circuit 2 and an output port circuit 4. Specifically, connection control circuit 5 responds to an output control signal to switch between an ON state and OFF state of first switch circuit SW1 to control the connection between digital-analog conversion circuit 2 and output port circuit 4. Output switch circuit 6 switches to provide a digital signal output or an analog signal output from output port circuit 4 to an external source. Specifically, output switch circuit 6 switches the connection of second switch elements SW2, SW3 to the side of processing circuit 1 or the side of output amplifier 42 based on a switch signal output to output a digital signal or an analog signal from output port circuit 4.

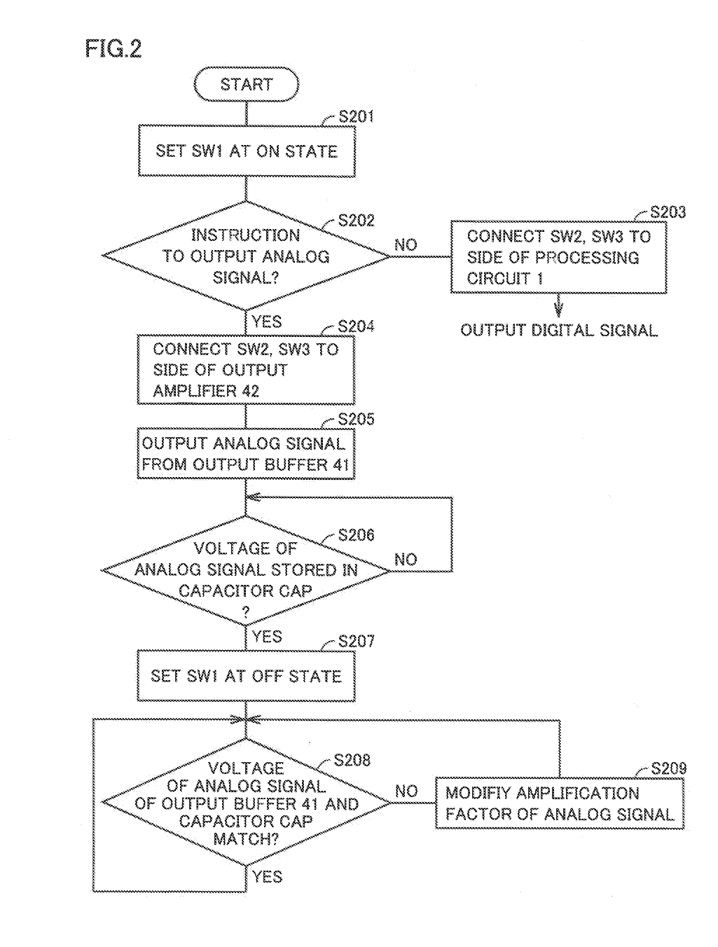

An operation of semiconductor processing device 10 according to the first embodiment of the present invention will be described hereinafter. FIG. 2 is a flowchart to describe an operation of semiconductor processing device 10 according to the first embodiment of the present invention. First, output control circuit 3 has the desired voltage of an analog signal to be output from digital-analog conversion circuit 2 set in advance. Then, connection control circuit 5 drives first switch element SW1 to an ON state (step S201). Further, output control circuit 3 instructs digital-analog conversion circuit 2 to output an analog signal converted at digital-analog conversion circuit 2.

Then, output switch circuit 6 determines whether processing circuit 1 has instructed output of an analog signal from output port circuit 4 (step S202). When output switch circuit 6 determines that processing circuit 1 has not instructed output of an analog signal from output port circuit 4 (step 5202: NO), output switch circuit 6 connects second switch elements SW2, SW3 to the side of processing circuit 1 (step S203). By connecting second switch elements SW2, SW3 to the side of processing circuit 1 in semiconductor processing device 10, a digital signal is output from output port circuit 4.

In the case where output switch circuit 6 determines that processing circuit 1 has instructed output of an analog signal from output port circuit 4 (step S202: YES), output switch circuit 6 connects second switch elements SW2, SW3 to the side of output amplifier 42 (step S204). By connecting second switch elements SW2, SW3 to the side of output amplifier 42 (step S204), semiconductor processing device 10 has an analog signal output from output buffer 41 in output port circuit 4 (step S205).

Then, output port circuit 4 determines whether the voltage of an analog signal output from digital-analog conversion circuit 2 is stored in capacitor CAP or not (step S206). When output port circuit 4 determines that the voltage of an analog signal output from digital-analog conversion circuit 2 is not stored in capacitor CAP (step S206: NO), output port circuit 4 repeats the processing of step S206.

When output port circuit 4 determines that the voltage of an analog signal output from digital-analog conversion circuit 2 is stored in capacitor CAP (step S206: YES), connection control circuit 5 drives first switch element SW1 to an OFF state (step S207). In addition, output control circuit 3 instructs digital-analog conversion circuit 2 to stop output of an analog signal converted at digital-analog conversion circuit 2.

Then, output amplifier 42 compares the voltage of an analog signal output from output buffer 41 with the voltage of an analog signal stored in capacitor CAP (the voltage of an analog signal output from digital-analog conversion circuit 2), and determines whether they match (step S208). When output amplifier 42 determines that the voltage of an analog signal output from output buffer 41 does not match the voltage of an analog signal stored in capacitor CAP (step S208: NO), output amplifier 42 modifies the amplification factor of an analog signal based on a difference (a compared result) between the voltage of an analog signal output from output buffer 41 and a voltage of an analog signal stored in capacitor CAP (step S209). Following step S209, output amplifier 42 returns to the processing of step S208, and carries out again the comparison between the voltage of an analog signal output from output buffer 41 subsequent to modification of the amplification factor for the analog signal with the voltage of an analog signal stored in capacitor CAP to determine whether they match or not.

When output amplifier 42 determines that the voltage of an analog signal output from output buffer 41 matches the voltage of an analog signal stored in capacitor CAP (step S208: YES), output amplifier 42 repeats feedback control. By repeating such feedback control, semiconductor processing device 10 stably outputs an analog signal of a desired voltage from output port circuit 4. Although the description is based on providing an analog signal output from one output port circuit 4, an analog signal can be output from a plurality of output port circuits 4 by repeating a similar processing for the other output port circuits 4. By output control circuit 3 setting in advance a desired voltage of an analog signal to be output from digital-analog conversion circuit 2 for each output port circuit 4, the ON resistance of P channel MOS transistor 41a and N channel MOS transistor 41b can be controlled for every output port circuit 4.

Thus, since semiconductor processing device 10 according to the first embodiment of the present invention has the ON resistance of output buffer 41 providing a digital signal output controlled to output an analog signal from output buffer 41, an analog signal can be output from output port circuit 4 that provides a digital signal output. Therefore, semiconductor processing device 10 can have an output port circuit 4 providing a digital signal output and an output port circuit 4 providing an analog signal output used in common, allowing the number of output port circuits 4 to be reduced for down-sizing. Furthermore, since semiconductor processing device 10 uses output buffer 41 to provide an analog signal output from digital-analog conversion circuit through output port circuit 4, the impedance of a circuit (for example, a memory circuit, sensor circuit, or the like) connected to output port circuit 4 does not have to be aligned with the impedance of digital-analog conversion circuit 2. Therefore, a configuration in which there are a plurality of output port circuits 4 for one digital-analog conversion circuit 2 can be implemented.

Moreover, since semiconductor processing device 10 has the ON resistance of P channel MOS transistor 41a and N channel MOS transistor 41b in output buffer 41 controlled for every output port circuit 4 to output an analog signal, an analog signal of a different voltage can be output from output buffer 41 in each output port circuit 4.

(Second Embodiment)

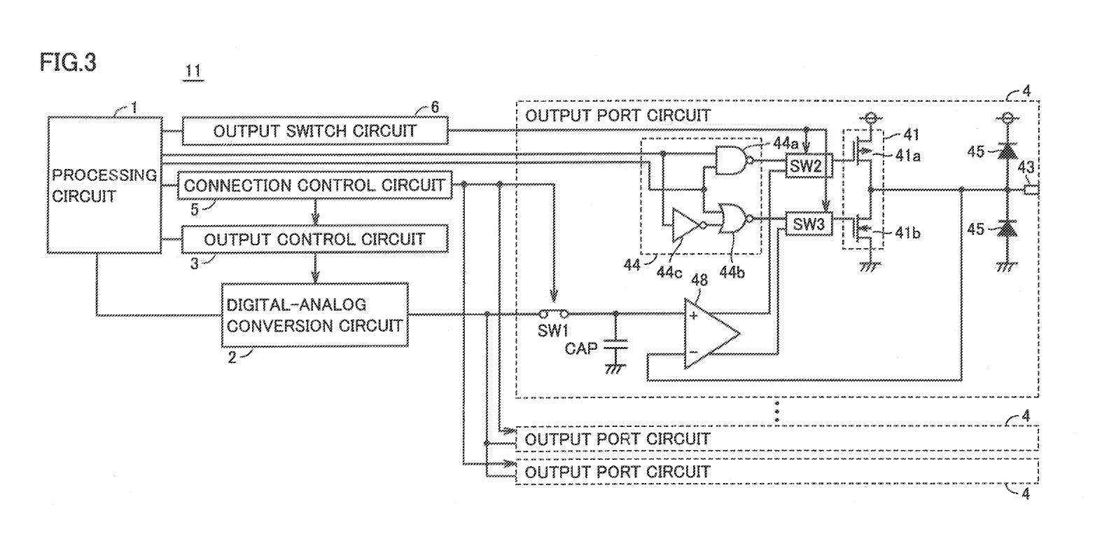

FIG. 3 is a schematic diagram representing a configuration of a semiconductor processing device according to a second embodiment of the present invention. A semiconductor processing device 11 of FIG. 3 includes a processing circuit 1, a digital-analog conversion circuit 2, an output control circuit 3, a plurality of output port circuits 4, a connection control circuit 5, and an output switch circuit 6. Semiconductor processing device 11 has a configuration similar to that of semiconductor processing device 10 according to the first embodiment of the present invention except for including an output amplifier 48 instead of output amplifier 42 in output port circuit 4. Therefore, the same constituent elements have the same reference characters allotted, and detailed description thereof will not be repeated.

Output amplifier 42 shown in FIG. 1 outputs the same analog signal to each of second switch elements SW2, SW3. In other words, output amplifier 42 outputs the same analog signal to the gate terminals of P channel MOS transistor 41a and N channel MOS transistor 41b. Therefore, output buffer 41 controls the ON resistance of P channel MOS transistor 41a and N channel MOS transistor 41b based on the same analog signal.

In contrast, output amplifier 48 of FIG. 3 can output an analog signal of a positive level and an analog signal of an inverted level, differing from output amplifier 42. An analog signal of a positive level is output to second switch element SW2 whereas an analog signal of an inverted level is output to second switch element SW3. In other words, output amplifier 48 outputs a different analog signal to the gate terminal of P channel MOS transistor 41a and to the gate terminal of N channel MOS transistor 41b. Therefore, output buffer 41 can control independently the ON resistance of P channel MOS transistor 41a and the ON resistance of N channel MOS transistor 41b based on difference analog signals.

Semiconductor processing device 11 is not limited to a configuration in which a plurality of output port circuits 4 are connected to one digital-analog conversion circuit 2. A configuration in which one output port circuit 4 is connected to one digital-analog conversion circuit 2 may be implemented. Furthermore, semiconductor processing device 11 may have a configuration in which there is a mixture of an output port circuit 4 including output amplifier 42 and an output port circuit 4 including output amplifier 48. The operation of semiconductor processing device 11 is similar to that of semiconductor processing device 10 according to the first embodiment. Therefore, detailed description of the operation will not be repeated.

Thus, since semiconductor processing device 11 according to the second embodiment of the present invention has output amplifier 48 provide a different analog signal to P channel MOS transistor 41a in output buffer 41 and N channel MOS transistor 41b in output buffer 41, the ON resistance of P channel MOS transistor 41a and the ON resistance of N channel MOS transistor 41b can be controlled individually based on different analog signals. Thus, the voltage of an analog signal output from output buffer 41 can be controlled at high accuracy.

Although a semiconductor processing device according to subsequent embodiments will be described based on a configuration in which a control signal from output amplifier 42 or output amplifier 48 to second switch elements SW2, SW3 corresponds to that in the drawing related to the first embodiment, it is intended that the configuration indicated in the drawings related to the second embodiment is also encompassed.

(Third Embodiment)

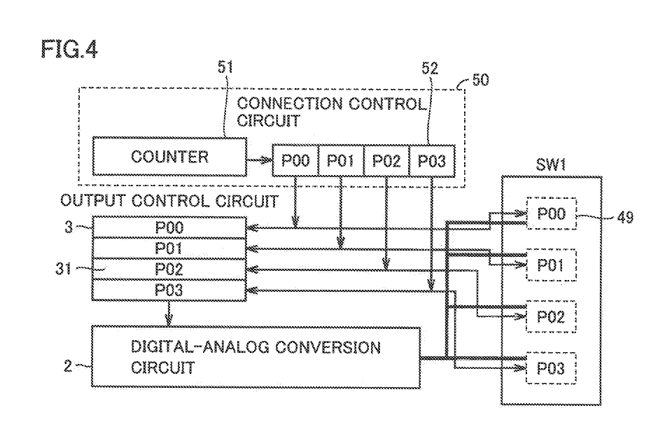

In a semiconductor processing device according to a third embodiment of the present invention, a connection control circuit includes a counter. The connection control circuit sequentially controls first switch element SW1 in a plurality of output port circuits according to the counter. FIG. 4 is a schematic diagram representing a configuration of a connection control circuit 50 in a semiconductor processing device according to the third embodiment of the present invention. FIG. 4 depicts, in addition to connection control circuit 50, a digital-analog conversion circuit 2, an output control circuit 3, and first switch element SW1 in an output port circuit. Since the constituent elements of the semiconductor processing device according to the third embodiment not shown in FIG. 4 are similar to those in semiconductor processing device 10 according to the first embodiment shown in FIG. 1, description is provided hereinafter based on the same reference characters without illustration thereof.

Connection control circuit 50 shown in FIG. 4 includes a counter 51, and a register 52 storing a port number of an output port circuit 4. Counter 51 sequentially selects a port number of an output port circuit 4 stored in register 52 at a constant interval. Register 52 outputs a control signal corresponding to the port number of output port circuit 4 selected at counter 51 to output control circuit 3 and to first switch element SW1 in output port circuit 4. Output control circuit 3 and first switch element SW1 in output port circuit 4 include registers 31 and 49, respectively, storing processing information corresponding to the port number of each output port circuit 4. Therefore, output control circuit 3 and first switch element SW1 in output port circuit 4 execute the processing information corresponding to the port number of output port circuit 4 based on a control signal output from connection control circuit 50 (register 52).

For example, when a control signal corresponding to port number PO of output port circuit 4 is output from connection control circuit 50, output control circuit 3 and first switch element SW1 in output port circuit 4 execute the processing information stored in registers 31 and 49 corresponding to port number PO of output port circuit 4. Output control circuit 3 executes the processing information stored in register 31 to set in advance the desired voltage of an analog signal to be output from digital-analog conversion circuit 2, and instructs digital-analog conversion circuit 2 to output an analog signal converted at digital-analog conversion circuit 2. First switch element SW1 in output port circuit 4 attains an ON state from an OFF state by executing the processing information stored in register 49. In response to counter 51 sequentially selecting a port number of an output port circuit stored in register 52 at a constant interval, similar processing is carried out for port numbers P1 to P3 of output port circuits 4. The port number of an output port circuit 4 is not limited to PO to P3.

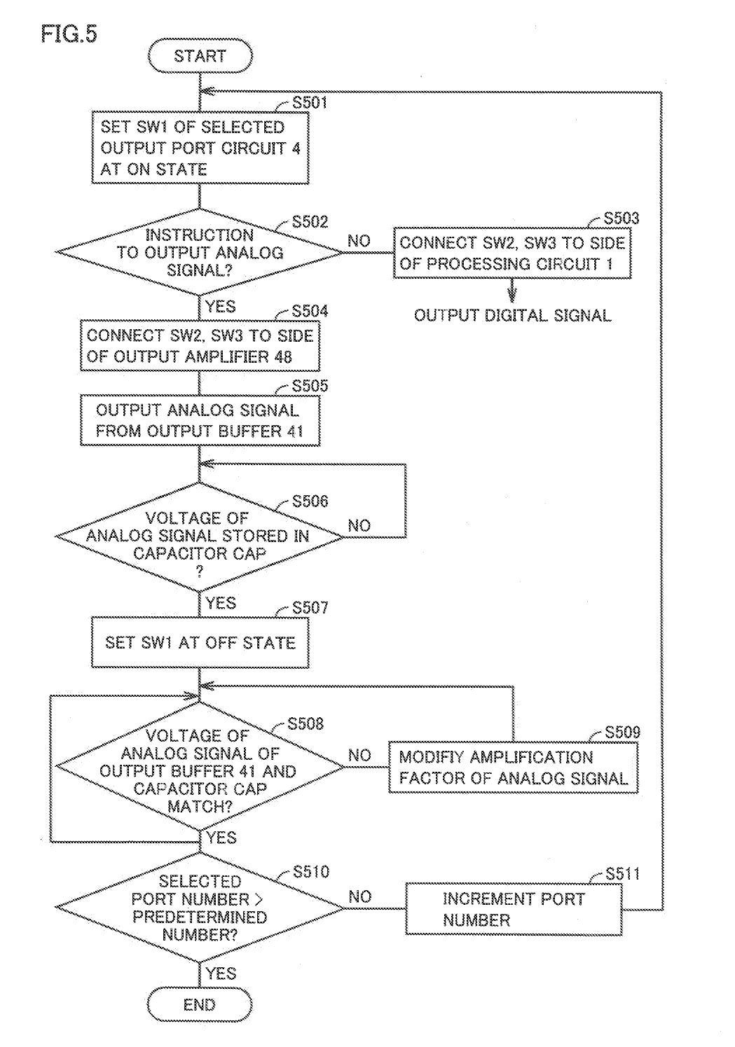

An operation of the semiconductor processing device according to the third embodiment of the present invention will be described hereinafter. FIG. 5 is a flowchart to describe an operation of the semiconductor processing device according to the third embodiment of the present invention. First, counter 51 selects one port number of an output port circuit 4 stored in register 52. Output control circuit 3 executes processing information stored in register 31 corresponding to the port number of an output port circuit 4 selected at counter 51 Output control circuit 3 executes the processing information stored in register 31 to set in advance the desired voltage of an analog signal to be output from digital-analog conversion circuit 2. Connection control circuit 5 sets first switch element SW1 corresponding to the port number of an output port circuit 4 selected at counter 51 at an ON state (step S501). In addition, output control circuit 3 executes the processing information stored in register 31 to instruct digital-analog conversion circuit 2 to output an analog signal converted at digital-analog conversion circuit 2.

Then, output switch circuit 6 determines whether processing circuit 1 has instructed output of an analog signal from output port circuit 4 (step S502). When output switch circuit 6 determines that processing circuit 1 has not instructed output of an analog signal from output port circuit 4 (step S502: NO), output switch circuit 6 connects second switch elements SW2, SW3 to the side of processing circuit 1 (step S503). By connecting second switch elements SW2, SW3 to the side of processing circuit 1 in the semiconductor processing device, a digital signal is output from output port circuit 4.

In the case where output switch circuit 6 determines that processing circuit 1 has instructed output of an analog signal from output port circuit 4 (step S502: YES), output switch circuit 6 connects second switch elements SW2, SW3 to the side of output amplifier 42 (step S504). By connecting second switch elements SW2, SW3 to the side of output amplifier 42, the semiconductor processing device has an analog signal output from output port circuit 4 (step S505).

Then, output port circuit 4 determines whether the voltage of an analog signal output from digital-analog conversion circuit 2 is stored in capacitor CAP or not (step S506). When output port circuit 4 determines that the voltage of an analog signal output from digital-analog conversion circuit 2 is not stored in capacitor CAP (step S506: NO), output port circuit 4 repeats the processing of step S506.

When output port circuit 4 determines that the voltage of an analog signal output from digital-analog conversion circuit 2 is stored in capacitor CAP (step S506: YES), connection control circuit 5 drives first switch element SW1 corresponding to the port number of output port circuit 4 selected at counter 51 to an OFF state (step S507). In addition, output control circuit 3 executes the processing information stored in register 31 and instructs digital-analog conversion circuit 2 to stop output of an analog signal converted at digital-analog conversion circuit 2.

Then, output amplifier 42 compares the voltage of an analog signal output from output buffer 41 with the voltage of an analog signal stored in capacitor CAP (the voltage of an analog signal output from digital-analog conversion circuit 2), and determines whether they match (step S508). When output amplifier 42 determines that the voltage of an analog signal output from output buffer 41 does not match the voltage of an analog signal stored in capacitor CAP (step S508: NO), output amplifier 42 modifies the amplification factor of an analog signal based on a difference (a compared result) between the voltage of an analog signal output from output buffer 41 and a voltage of an analog signal stored in capacitor CAP (step S509). Following step S509, output amplifier 42 returns to the processing of step S206, and carries out again the comparison between the voltage of an analog signal output from output buffer 41 subsequent to modification of the amplification factor for the analog signal with the voltage of an analog signal stored in capacitor CAP to determine whether they match or not.

When output amplifier 42 determines that the voltage of an analog signal output from output buffer 41 matches the voltage of an analog signal stored in capacitor CAP (step S508: YES), counter 51 determines whether the port number of the selected output port circuit 4 exceeds a predetermined number or not (step S510). When output amplifier 42 determines that the voltage of an analog signal output from output buffer 41 matches the voltage of an analog signal stored in capacitor CAP, semiconductor processing device 10 repeats feedback control (step S508). An analog signal of a desired voltage is stably output from output port circuit 4 as a current source.

When counter 51 determines that the port number of selected output port circuit 4 does not exceed a predetermined number (step S510: NO), counter 51 increments by 1 the port number of output port circuit 4 to be selected (step S511). For example, counter 51 increments by 1 the port number of output port circuit 4 to be selected from PO to P1. After counter 51 increments by 1 the port number of output port circuit 4 to be selected, control returns to step S501.

When counter 51 determines that the port number of selected output port circuit 4 exceeds a predetermined number (step S510: YES), the semiconductor processing device terminates the processing.

Thus, in the semiconductor processing device according to the third embodiment of the present invention, connection control circuit 5 includes counter 51 sequentially selecting a port number of an output port circuit 4 set corresponding to each of a plurality of output port circuits 4. Since output control circuit 3 sets in advance the voltage of an analog signal converted at digital-analog conversion circuit 2 corresponding to the port number of an output port circuit 4 selected at counter 51, and connection control circuit 5 sets first switch element SW1 in output port circuit 4 corresponding to the port number of an output port circuit 4 selected at counter 51 at an ON state, the processing of processing circuit 1 to sequentially switch a plurality of output port circuits 4 is no longer required, allowing the load of processing at processing circuit 1 to be alleviated. In the case where output port circuit 4 includes a capacitor CAP storing the voltage of an analog signal output from digital-analog conversion circuit 2, the semiconductor processing device can have the port number of an output port circuit 4 sequentially selected at counter 51 to sequentially supply the voltage of an analog signal output from digital-analog conversion circuit 2 and stored in capacitor CAP. Therefore, the semiconductor processing device can stably store the voltage of an analog signal output from digital-analog conversion circuit 2 in capacitor CAP. Thus, the voltage of an analog signal output from output buffer 41 can be controlled at high accuracy.

(Fourth Embodiment)

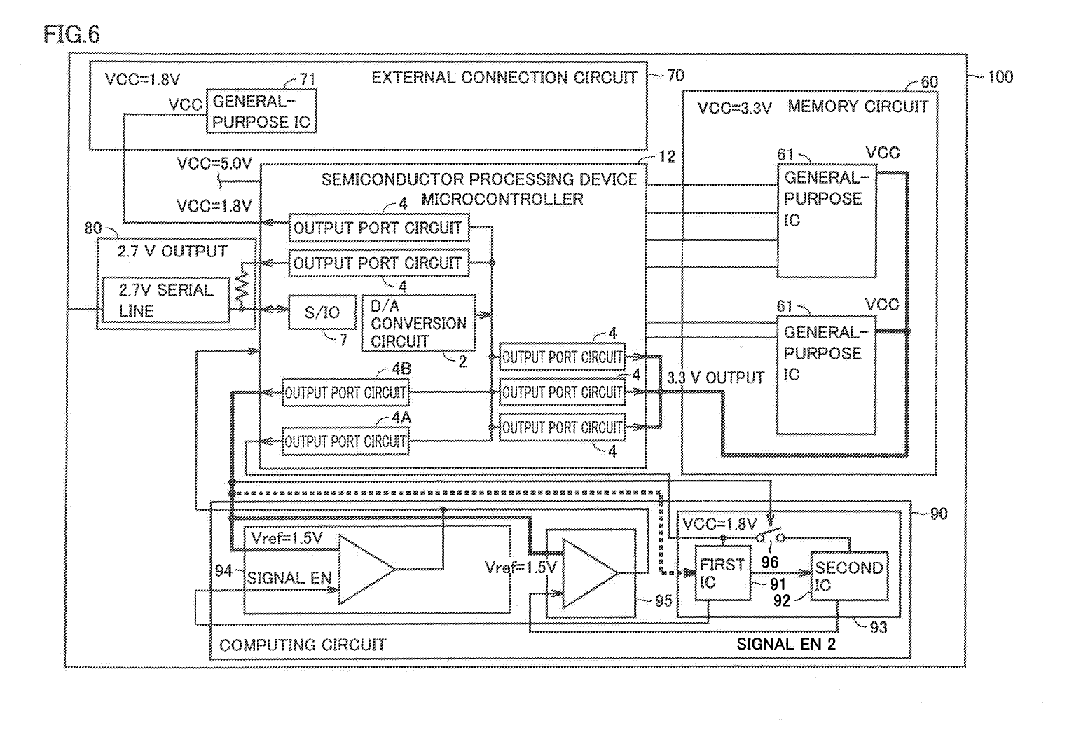

FIG. 6 is a schematic diagram representing a configuration of a semiconductor processing system according to a fourth embodiment of the present invention. A semiconductor processing system 100 of FIG. 6 includes a semiconductor processing device 12, a memory circuit 60, an external connection circuit 70, a communication circuit 80, and a computing circuit 90.

Semiconductor processing device 12 is a semiconductor processing device described in the first to third embodiments, allowing output of a digital signal or analog signal from output port circuit 4. Semiconductor processing device 12 supplies voltage by providing an analog signal from output port circuit 4 to connected memory circuit 60, external connection circuit 70, communication circuit 80 and computing circuit 90 to also function as a power supply. Semiconductor processing device 12 has a voltage of 5.0 V supplied from an external power supply.

Memory circuit 60 is a storage circuit such as a DRAM, including two general-purpose ICs 61 driven at the voltage of 3.3 V. General-purpose IC 61 receives an analog signal of voltage 3.3 V from output port circuit 4 of semiconductor processing device 12 at the VCC terminal for driving. Although general-purpose IC 61 requires a high-amperage current for driving a memory element not shown, the current of an analog signal output from output port circuit 4 is smaller as compared to the high-amperage current for driving a memory element. Therefore, semiconductor processing system 100 supplies a high-amperage current required for general-purpose IC 61 by connecting a plurality of output port circuits 4 to memory circuit 60. For example, in the case where the current of an analog signal that can be output from one output port circuit 4 is 20 mA and a high-amperage current required for driving general-purpose IC 61 is 60 mA, the required high-amperage current for general-purpose IC 61 is supplied by connecting three output port circuits 4 to memory circuit 60. For transmitting and receiving data between memory circuit 60 and semiconductor processing device 12, connection is established between memory circuit 60 and semiconductor processing device 12 through means other than output port circuit 4.

External connection circuit 70 is, for example, an interface circuit for connecting with an external storage device, and includes one general-purpose IC 71 driven at the voltage of 1.8 V. For driving, general-purpose IC 71 receives an analog signal of voltage 1.8 V from output port circuit 4 of semiconductor processing device 12 at the VCC terminal.

Communication circuit 80 is a communication port for data communication with an external device, and is a circuit that can supply a voltage of 2.7 V to a connected external device. Communication circuit 80 receives an analog signal of voltage 2.7 V from output port circuit 4 of semiconductor processing device 12 to supply a voltage of 2.7 V to an external device. Communication circuit 80 is also connected with a serial input/output port (SI/O) 7 of semiconductor processing device 12 to perform data communication between semiconductor processing device 12 and an external device.

Computing circuit 90 is, for example, a circuit for carrying out processing on a digital signal output from semiconductor processing device 12, and includes a first IC 91 and a second IC 92 constituting a computing unit 93, a first power supply detection circuit 94 detecting a rise of the power supply of a first IC 91, and a second power supply detection circuit 95 detecting a rise of the power supply of a second IC 92. Each of first and second ICs 91 and 92 outputs a voltage corresponding to the level of the supplied voltage as an operation enable signal (signal EN). Computing circuit 90 first receives a voltage of 1.5 V from output port circuit 4B, and an analog signal of voltage 1.8 V from output port circuit 4A at first IC 91 for driving first IC 91. When driven, first IC 91 outputs an operation enable signal (signal EN) to first power supply detection circuit 94. First power supply detection circuit 94 compares an analog signal of voltage 1.5 V (reference voltage) output from output port circuit 4B with the voltage of signal EN of first IC 91. When the voltage of signal EN is higher than the reference voltage, a first detection signal detecting the rise of the power supply of first IC 91 is output to semiconductor processing device 12. During a certain period immediately after the power is turned ON, switch 96 takes an OFF state.

Semiconductor processing device 12 alters output port circuit 4B to a digital output operation state based on the first detection signal, and outputs an H voltage (for example 2.2 V) directed to setting switch 96 in computing unit 93 at an ON state. Thus, switch 96 attains an ON state. Switch 96 is configured to exhibit hysteresis characteristics, with the voltage changing from an OFF state to an ON state set at 2.0 V, and the voltage changing from an ON state to an OFF state set at 1.0 V. Then, output port circuit 4B is altered to an analog output operation state to begin the output of a reference voltage 1.5 V of second power supply detection circuit 95. By applying an analog signal of voltage 1.8 V from output port circuit 4A to second IC 92, second IC 92 is driven. The drive of second IC 92 causes second IC 92 to output an operation enable signal (signal EN2) to second power supply detection circuit 95. Second power supply detection circuit 95 compares the analog signal of voltage 1.5 V (reference voltage) output from output port circuit 4B with the voltage of signal EN2 of first IC 91. When the voltage of signal EN2 is higher than the reference voltage, a second detection signal detecting the rise of the power supply of second IC 92 is output to semiconductor processing device 12. Semiconductor processing device 12 outputs a data transfer start signal (start signal) from output port circuit 4B and a digital signal sequentially to first IC 91, based on the second detection signal.

As described in the first to third embodiments, since semiconductor processing device 12 controls the ON resistance of P channel MOS transistor 41a and N channel MOS transistor 41b for every output port circuit 4 to output an analog signal from output buffer 41, an analog signal of a different voltage can be output from output buffer 41 of each output port circuit 4. Therefore, semiconductor processing device 12 can connect memory circuit 60 driven at voltage 3.3 V, external connection circuit 70 driven at voltage 1.8 V, communication circuit 80 supplying voltage 2.7 V, and computing circuit 90 driven at the voltage of 1.8 V and requiring the reference voltage of 0.8 V to output port circuit 4.

As described in association with the operation of output port circuit 4B, by setting the voltage for analog signal output at 1.5 V and the H voltage for a digital signal output at 2.2 V, the resetting of reference voltage for output port circuit 4B required at digital-analog conversion circuit 2 can be dispensed with at the switching between the output period of 1.5 V and the output period of 2.2 V.

Thus, semiconductor processing system 100 according to the fourth embodiment of the present invention includes a semiconductor processing device 12 that can output an analog signal of a different voltage from output buffer 41 of each of a plurality of output port circuits 4. Therefore, a circuit driven at an analog signal of a different voltage can be connected to semiconductor processing device 12 without having to include a plurality of digital-analog conversion circuits, voltage conversion circuits, and the like. Furthermore, output of a voltage of a different level is facilitated by switching between a digital signal output state and an analog signal output state, allowing semiconductor processing system 100 to be down-sized. When the operation of first IC 91 and second IC 92 is started at the same time, power consumption is increased to cause deficiency such as noise generation. In order to avoid the deficiency of noise generation and the like, semiconductor processing system 100 can readily set an appropriate time difference in starting the operation between first IC 91 and second IC 92, as compared to a configuration avoiding simultaneous start of the operation of first IC 91 and second IC 92 using a timer.

(Fifth Embodiment)

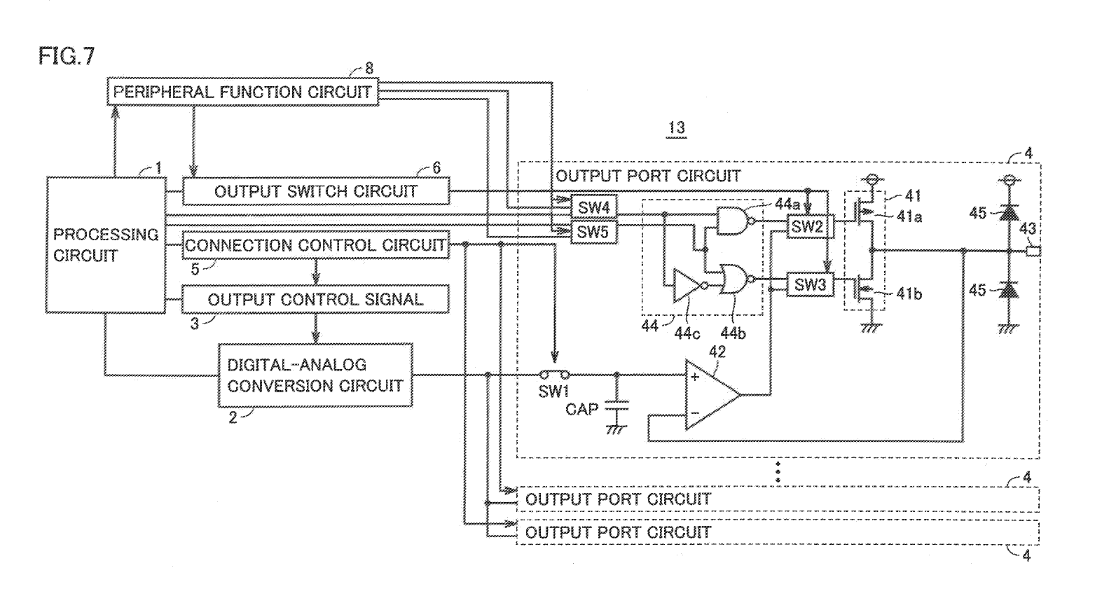

FIG. 7 is a schematic diagram representing a configuration of a semiconductor processing device according to a fifth embodiment of the present invention. A semiconductor processing device 13 of FIG. 7 corresponds to the configuration of semiconductor processing device 10 shown in FIG. 1 with an addition of a peripheral function circuit 8. For features identical to those in semiconductor processing device 10 of FIG. 1, semiconductor processing device 13 has the same reference characters allotted, and detailed description thereof will not be repeated. As used herein, peripheral function circuit 8 includes a timer circuit, a PWM (Pulse Width Modulation) circuit, and the like.

Output port circuit 4 can switch between a digital signal output from processing circuit 1, an analog signal output from digital-analog conversion circuit 2, and a digital signal output from peripheral function circuit 8. Output port circuit 4 includes a fourth switch element SW4 and a fifth switch element S5 to switch between a digital signal output from processing circuit 1 and a digital signal output from peripheral function circuit 8. Fourth switch element SW4 and fifth switch element SW5 serve to switch the connection between processing circuit 1 and logic circuit 44 to the connection between peripheral function circuit 8 and logic circuit 44.

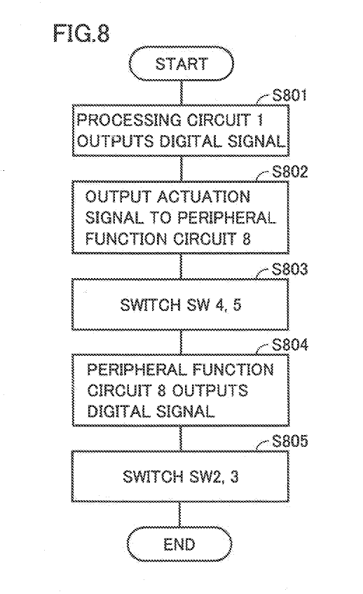

FIG. 8 is a flowchart to describe an operation of the semiconductor processing device according to the fifth embodiment of the present invention. First, processing circuit 1 uses output port circuit 4 to output a digital signal (step S801). Then, processing circuit 1 ends the usage of output port circuit 4, and outputs to peripheral function circuit 8 an actuation signal to actuate peripheral function circuit 8 (step S802). Peripheral function circuit 8 completes actuation to switch between fourth switch element SW4 and fifth switch element SW5 to output a digital signal (step S803). Specifically, peripheral function circuit 8 provides an output switch signal to each of fourth switch element SW4 and fifth switch element SW5 to switch the connection between processing circuit 1 and logic circuit 44 to the connection between peripheral function circuit 8 and logic circuit 44. Peripheral function circuit 8 must output a peripheral function output valid signal to output switch circuit 6 for switching second switch elements SW2, SW3 such that connection is established between output buffer 41 and logic circuit 44.

After fourth switch element SW4 and fifth switch element SW5 are switched, peripheral function circuit 8 uses output port circuit 4 to output a digital signal (step S804). Then, when peripheral function circuit 8 ends the usage of output port circuit 4 and digital-analog conversion circuit 2 uses output port circuit 4 to provide an analog signal output, peripheral function circuit 8 outputs a peripheral function output valid signal to output switch circuit 6, and switches second switch elements SW2, SW3 such that connection between output buffer 41 and digital-analog conversion circuit 2 is established (step S805).

Thus, the provision of fourth switch element SW4 and fifth switch element SW5 at output port circuit 4 in semiconductor processing device 13 according to the fifth embodiment of the present invention allows a digital signal output from peripheral function circuit 8, in addition to a digital signal output from processing circuit 1, by means of output port circuit 4.

(Sixth Embodiment)

Semiconductor processing device 12 shown in FIG. 6 functions as a power supply delivering a predetermined voltage by providing an analog signal output from output port circuit 4 to memory circuit 60, external connection circuit 70, communication circuit 80, and computing circuit 90. Semiconductor processing device 12 functioning as a power supply is mainly classified into a power supply delivering a reference voltage (reference power supply), and a power supply delivering a current (current source). Specifically, semiconductor processing device 12 outputs, as reference voltage, an analog signal of voltage 1.5 V output from output port circuit 4B to first power supply detection circuit 94 and second power supply detection circuit 95 in computing circuit 90. Also, semiconductor processing device 12 outputs, as a power supply voltage, an analog signal of voltage 3.3 V output from output port circuit 4B to memory circuit 60, external connection circuit 70, and the like to supply a current for driving a memory element.

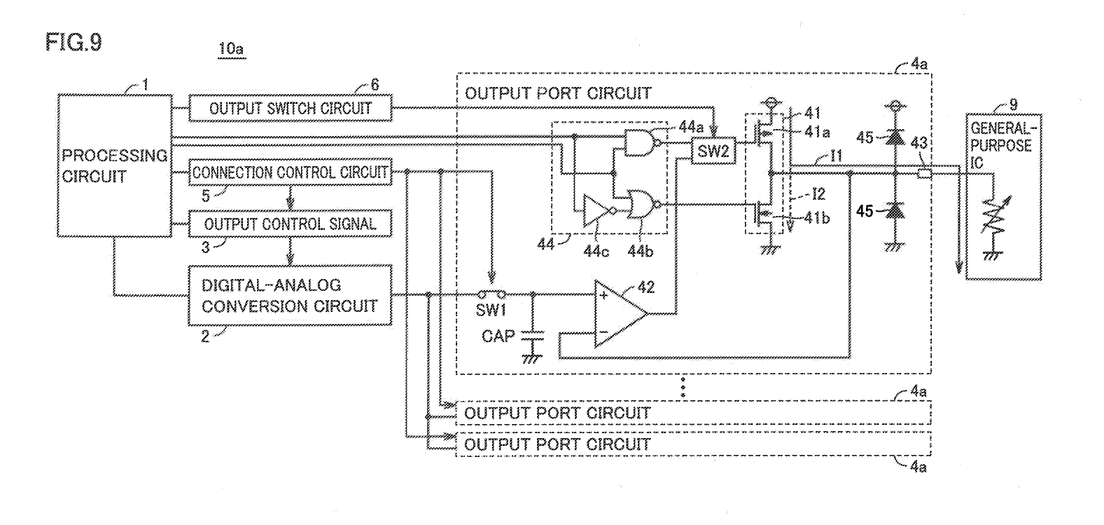

A semiconductor processing device according to a sixth embodiment of the present invention is directed to a configuration in which current consumption can be reduced when functioning as a power supply delivering a current. FIG. 9 schematically represents a configuration of a semiconductor processing device according to the sixth embodiment of the present invention.

A semiconductor processing device 10a shown in FIG. 9 includes a processing circuit 1, a digital-analog conversion circuit 2, an output control circuit 3, a plurality of output port circuits 4a, a connection control circuit 5, and an output switch circuit 6. Semiconductor processing device 10a has a configuration similar to that of semiconductor processing device 10 according to the first embodiment of the present invention, except for the configuration of an output port circuit 4a. Therefore, the same constituent elements have the same reference characters allotted, and detailed description thereof will not be repeated.

Output port circuit 4 shown in FIG. 1 includes second switch elements SW2, SW3 connected to the gate terminals of P channel MOS transistor 41a and N channel MOS transistor 41b. Second switch elements SW2, SW3 respond to a switch signal output from output switch circuit 6 to switch the connection to the side of processing circuit 1 or to the side of output amplifier 42.

When second switch elements SW2, SW3 are connected to the side of output amplifier 42 (when output buffer 41 and output amplifier 42 are connected) in output port circuit 4 shown in FIG. 1, an analog signal amplified at output amplifier 42 is input to the gate terminals of P channel MOS transistor 41a and N channel MOS transistor 41b. Output port circuit 4 shown in FIG. 1 controls the ON resistance of P channel MOS transistor 41a and N channel MOS transistor 41b. By controlling the ON resistance of P channel MOS transistor 41a and N channel MOS transistor 41b, output port circuit 4 of FIG. 1 can output from output buffer 41 an analog signal of a voltage in the range between the voltage supplied as a power supply voltage and ground voltage taking into account the threshold voltage of each MOS transistor.

Output port circuit 4 shown in FIG. 1 is connected to a general-purpose IC, and semiconductor processing device 10 is made to function as a power supply delivering a current to drive the general-purpose IC. In this case, in addition to a current I1 flowing to the general-purpose IC from the power supply via P channel MOS transistor 41a, a current I2 flowing from the power supply to ground via P channel MOS transistor 41a and N channel MOS transistor 41b will be required constantly. Thus, there is a problem that the consumed current is increased since semiconductor processing device 10 must have the flow of current I1+I2 for driving the general-purpose IC.

In view of the foregoing, a semiconductor processing device 10a according to the sixth embodiment of the present invention includes an output port circuit 4a instead of output port circuit 4 shown in FIG. 1 to reduce the consumed current. Output port circuit 4a shown in FIG. 9 includes a second switch element SW2 connected to the gate terminal of P channel MOS transistor 41 a In other words, a second switch element SW3 is not connected to the gate terminal of N channel MOS transistor 41b. NOR circuit 44b of logic circuit 44 is directly connected to the gate terminal of N channel MOS transistor 41b. Second switch element SW2 responds to a switch signal from output switch circuit 6 to switch the connection between the side of processing circuit 1 and the side of output amplifier 42.

When second switch element SW2 is connected to the side of output amplifier 42 (when output buffer 41 and output amplifier 42 are connected) in output port circuit 4a, the analog signal amplified at output amplifier 42 is input to the gate terminal of P channel MOS transistor 41a. Then, output port circuit 4a controls the ON resistance of P channel MOS transistor 41a.

When general-purpose IC 9 is connected to output port circuit 4a, output port circuit 4a can output an analog signal from output buffer 41 to supply a current to general-purpose IC 9 by controlling the ON resistance of P channel MOS transistor 41a. The voltage of an analog signal output from output port circuit 4a takes a divided value of the power supply voltage based on the ON resistance of P channel MOS transistor 41a and the ON resistance of general-purpose IC 9. N channel MOS transistor 41b attains an OFF state in response to NOR circuit 44b providing a logic output of L as an OFF signal. In the case where an off leak channel current flowing to N channel MOS transistor 41b caused by process variation is to be taken into account, logic L output from NOR circuit 44b may be a negative voltage. The same applies to a semiconductor processing device according to embodiments set forth below.

In the case where general-purpose IC 9 is connected to output port circuit 4a and semiconductor processing device 10a is made to function as a power supply delivering a current directed to driving relevant general-purpose IC 9, only current I1 flowing from the power supply to general-purpose IC 9 via P channel MOS transistor 41a is required. In other words, current I2 flowing from the power supply to ground via P channel MOS transistor 41a and N channel MOS transistor 41b is not required since N channel MOS transistor 41b takes an OFF state. Thus, consumed current can be reduced since semiconductor processing device 10a can drive general-purpose IC 9 by just the flow of current I1.

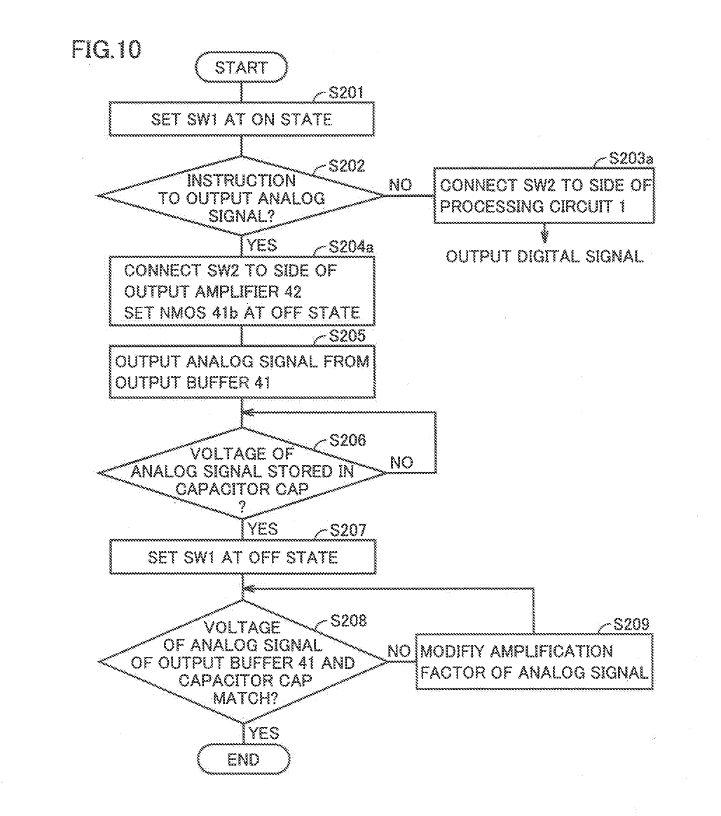

An operation of semiconductor processing device 10a according to the sixth embodiment of the present invention will be described hereinafter. FIG. 10 is a flowchart to describe an operation of semiconductor processing device 10a according to the sixth embodiment of the present invention. Steps identical to those in the flowchart of FIG. 2 will be described having the same reference characters allotted. First, output control circuit 3 has the desired voltage of an analog signal to be output from digital-analog conversion circuit 2 set in advance. Then, connection control circuit 5 drives first switch element SW1 to an ON state (step S201). Further, output control circuit 3 instructs digital-analog conversion circuit 2 to output an analog signal converted at digital-analog conversion circuit 2.

Then, output switch circuit 6 determines whether processing circuit 1 has instructed output of an analog signal from output port circuit 4a (step S202). When output switch circuit 6 determines that processing circuit 1 has not instructed output of an analog signal from output port circuit 4a (step S202: NO), output switch circuit 6 connects second switch element SW2 to the side of processing circuit 1 (step S203a). By connecting second switch element SW2 to the side of processing circuit 1 in semiconductor processing device 10, a digital signal is output from output port circuit 4.

In the case where output switch circuit 6 determines that processing circuit 1 has instructed output of an analog signal from output port circuit 4a (step S202: YES), output switch circuit 6 connects second switch element SW2 to the side of output amplifier 42 (step S204a). When output switch circuit 6 connects second switch element SW2 to the side of output amplifier 42, logic circuit 44 sets N channel MOS transistor 41b at an OFF state. By connecting second switch element SW2 to the side of output amplifier 42 (step S204a), semiconductor processing device 10a has an analog signal output from output buffer 41 in output port circuit 4a (step S205). At this stage, semiconductor processing device 10a outputs from output port circuit 4a an analog signal that takes a divided value of the power supply voltage based on the ON resistance of P channel MOS transistor 41a and the ON resistance of general-purpose IC 9.

Then, output port circuit 4a determines whether the voltage of an analog signal output from digital-analog conversion circuit 2 is stored in capacitor CAP or not (step S206). When output port circuit 4a determines that the voltage of an analog signal output from digital-analog conversion circuit 2 is not stored in capacitor CAP (step S206: NO), output port circuit 4a repeats the processing of step S206.

When output port circuit 4a determines that the voltage of an analog signal output from digital-analog conversion circuit 2 is stored in capacitor CAP (step S206: YES), connection control circuit 5 drives first switch element SW1 to an OFF state (step S207). In addition, output control circuit 3 instructs digital-analog conversion circuit 2 to stop output of an analog signal converted at digital-analog conversion circuit 2.

Then, output amplifier 42 compares the voltage of an analog signal output from output buffer 41 with the voltage of an analog signal stored in capacitor CAP (the voltage of an analog signal output from digital-analog conversion circuit 2), and determines whether they match (step S208). When output amplifier 42 determines that the voltage of an analog signal output from output buffer 41 does not match the voltage of an analog signal stored in capacitor CAP (step S208: NO), output amplifier 42 modifies the amplification factor of an analog signal based on a difference (a compared result) between the voltage of an analog signal output from output buffer 41 and the voltage of an analog signal stored in capacitor CAP (step S209). Following step S209, output amplifier 42 returns to the processing of step S208, and carries out again the comparison between the voltage of an analog signal output from output buffer 41 subsequent to modification of the amplification factor for the analog signal with the voltage of an analog signal stored in capacitor CAP to determine whether they match or not.

When output amplifier 42 determines that the voltage of an analog signal output from output buffer 41 matches the voltage of an analog signal stored in capacitor CAP (step S208: YES), output amplifier 42 repeats feedback control. By repeating such feedback control, semiconductor processing device 10a stably outputs an analog signal of a desired voltage from output port circuit 4a as a current source. Although the description is based on providing an analog signal output from one output port circuit 4a, an analog signal can be output from a plurality of output port circuits 4a by repeating a similar processing for the other output port circuits 4a. By output control circuit 3 setting in advance a desired voltage of an analog signal to be output from digital-analog conversion circuit 2 for each output port circuit 4a, the ON resistance of P channel MOS transistor 41a can be controlled for every output port circuit 4a.

Thus, semiconductor processing device 10a according to the sixth embodiment of the present invention is absent of second switch element SW3, and controls the ON resistance of P channel MOS transistor 41a with N channel MOS transistor 41b that provides a digital signal output at an OFF state to output an analog signal from output buffer 41. Therefore, semiconductor processing device 10a can have the current consumption at output buffer 41 reduced when an analog signal is output from output port circuit 4a.

Since semiconductor processing device 10a has an analog signal output from output buffer 41 with the ON resistance of P channel MOS transistor 41a controlled for each output port circuit 4a, an analog signal of a different voltage can be output from output buffer 41 of each output port circuit 4a.

Semiconductor processing device 10a is not limited to a configuration in which a plurality of output port circuits 4 are connected to one digital-analog conversion circuit 2. A configuration in which one output port circuit 4 is connected to one digital-analog conversion circuit 2 may be implemented. Furthermore, semiconductor processing device 10a may have a configuration in which there is a mixture of an output port circuit 4 including output amplifier 42 and an output port circuit 4 including output amplifier 48 shown in FIG. 3.

(Seventh Embodiment)

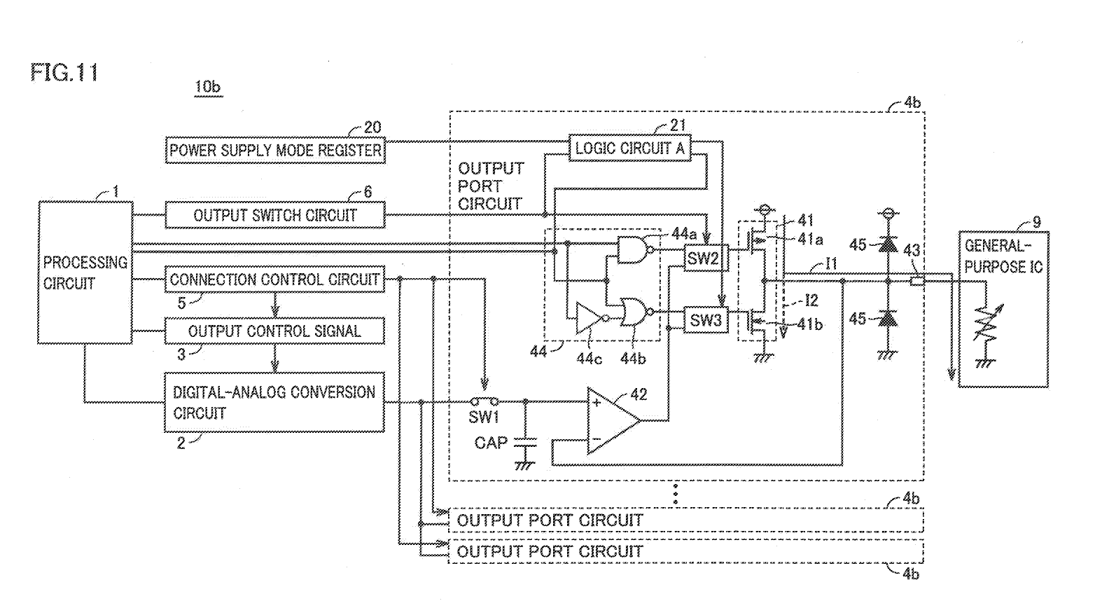

For a semiconductor processing device according to a seventh embodiment, another configuration allowing reduction of current consumption when functioning as a power supply delivering a current will be described. FIG. 11 schematically represents a configuration of a semiconductor processing device according to the seventh embodiment of the present invention.

A semiconductor processing device 10b of FIG. 11 includes a processing circuit 1, a digital-analog conversion circuit 2, an output control circuit 3, a plurality of output port circuits 4b, a connection control circuit 5, an output switch circuit 6, and a power supply mode register 20. Semiconductor processing device 10b has a configuration similar to that of semiconductor processing device 10 according to the first embodiment of the present invention, except for the configuration of output port circuit 4b and power supply mode register 20. Therefore, the same constituent elements have the same reference characters allotted, and detailed description thereof will not be repeated.

Semiconductor processing device 10b according to the seventh embodiment of the present invention includes, instead of output port circuit 4 in FIG. 1, an output port circuit 4b, and also a power supply mode register 20 to reduce current consumption. Output port circuit 4b of FIG. 11 includes second switch elements SW2, SW3 connected to the gate terminals of P channel MOS transistor 41a and N channel MOS transistor 41b. Second switch element SW2 switches the connection to the side of processing circuit 1 or to the side of output amplifier 42 based on a switch signal output from output switch circuit 6. Second switch element SW3 switches the connection between the side of processing circuit 1 or to the side of output amplifier 42 based on a switch signal output from logic circuit A 21.

Power supply mode register 20 outputs to output port circuit 4b a setting signal to set output port circuit 4b at a power supply mode delivering current to general-purpose IC 9 connected to output port circuit 4b. The setting signal output from power supply mode register 20 is input to logic circuit A 21 of output port circuit 4b. Logic circuit A 21 connects second switch element SW3 connected to the gate terminal of N channel MOS transistor 41b to the side of processing circuit 1 based on a switch signal output from output switch circuit 6 and a setting signal output from power supply mode register 20. Further, logic circuit A 21 provides control to output an OFF signal from NOR circuit 44b in logic circuit 44 such that N channel MOS transistor 41b attains an OFF state.

When second switch element SW2 is connected to the side of output amplifier 42 (when output buffer 41 and output amplifier 42 are connected) in output port circuit 4b, the analog signal amplified at output amplifier 42 is input to the gate terminal of P channel MOS transistor 41a. Then, output port circuit 4b controls the ON resistance of P channel MOS transistor 41a.

When general-purpose IC 9 is connected to output port circuit 4b, output port circuit 4b can output an analog signal from output buffer 41 to supply a current to general-purpose IC 9 by controlling the ON resistance of P channel MOS transistor 41a. The voltage of an analog signal output from output port circuit 4b takes a divided value of the power supply voltage based on the ON resistance of P channel MOS transistor 41a and the ON resistance of general-purpose IC 9.

In the case where general-purpose IC 9 is connected to output port circuit 4b and semiconductor processing device 10b is made to function as a power supply delivering a current directed to driving relevant general-purpose IC 9, only current I1 flowing from the power supply to general-purpose IC 9 via P channel MOS transistor 41a is required. In other words, current 12 flowing from the power supply to ground via P channel MOS transistor 41a and N channel MOS transistor 41b is not required since N channel MOS transistor 41b takes an OFF state. Thus, consumed current can be reduced since semiconductor processing device 10b can drive general-purpose IC 9 by just the flow of current I1.

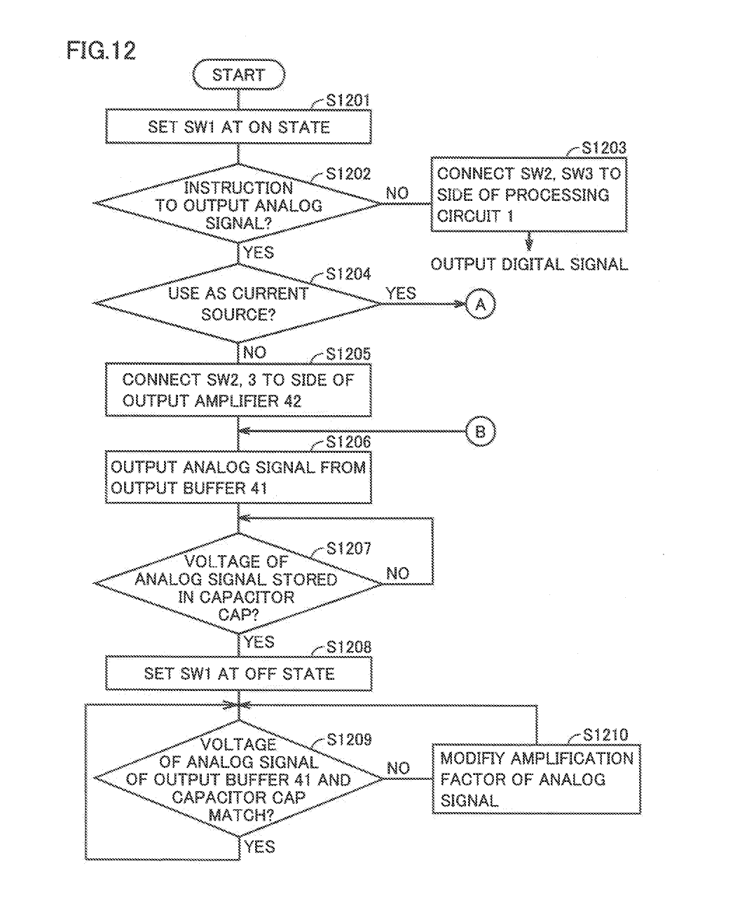

An operation of semiconductor processing device 10b according to the seventh embodiment of the present invention will be described hereinafter. FIG. 12 is a flowchart to describe an operation of semiconductor processing device 10b according to the seventh embodiment of the present invention. First, output control circuit 3 has the desired voltage of an analog signal to be output from digital-analog conversion circuit 2 set in advance. Then, connection control circuit 5 drives first switch element SW1 to an ON state (step S 1201). Further, output control circuit 3 instructs digital-analog conversion circuit 2 to output an analog signal converted at digital-analog conversion circuit 2.

Then, output switch circuit 6 determines whether processing circuit 1 has instructed output of an analog signal from output port circuit 4b (step S1202). When output switch circuit 6 determines that processing circuit 1 has not instructed output of an analog signal from output port circuit 4b (step S1202: NO), output switch circuit 6 connects second switch elements SW2, SW3 to the side of processing circuit 1 (step S1203). By connecting second switch elements SW2, SW3 to the side of processing circuit 1 in semiconductor processing device 10b, a digital signal is output from output port circuit 4b.

In the case where output switch circuit 6 determines that processing circuit 1 has instructed output of an analog signal from output port circuit 4b (step S1202: YES), power supply mode register 20 determines whether to use the analog signal as a current source for general-purpose IC 9 connected to output port circuit 4b (step S1204). When power supply mode register 20 determines not to use the analog signal as a current source of general-purpose IC 9 connected to output port circuit 4b (step S1204:NO), output switch circuit 6 connects second switch elements SW2, SW3 to the side of output amplifier 42 (step S1205). In other words, power supply mode register 20 determines usage as a power supply delivering a reference voltage to general-purpose IC 9 connected to output port circuit 4b.

By connecting second switch elements SW2, SW3 to the side of output amplifier 42 (step S1205), semiconductor processing device 10b outputs an analog signal from output buffer 41 of output port circuit 4b (step S1206).

Then, output port circuit 4b determines whether the voltage of an analog signal output from digital-analog conversion circuit 2 is stored in capacitor CAP (step S1207). When output port circuit 4b determines that the voltage of an analog signal output from digital-analog conversion circuit 2 is not stored in capacitor CAP (step S1207: NO), output port circuit 4b repeats the processing of step S1207.

When output port circuit 4b determines that the voltage of an analog signal output from digital-analog conversion circuit 2 is stored in capacitor CAP (step S1207: YES), connection control circuit 5 sets first switch element SW1 at an OFF state (step S1208). Output control circuit 3 instructs digital-analog conversion circuit 2 to stop the output of an analog signal converted at digital-analog conversion circuit 2.

Then, output amplifier 42 compares the voltage of an analog signal output from output buffer 41 with the voltage of an analog signal stored in capacitor CAP (the voltage of an analog signal output from digital-analog conversion circuit 2), and determines whether they match (step S1209). When output amplifier 42 determines that the voltage of an analog signal output from output buffer 41 does not match the voltage of an analog signal stored in capacitor CAP (step S1209: NO), output amplifier 42 modifies the amplification factor of an analog signal based on a difference (a compared result) between the voltage of an analog signal output from output buffer 41 and a voltage of an analog signal stored in capacitor CAP (step S1210). Following step S1210, output amplifier 42 returns to the processing of step S1209, and carries out again the comparison between the voltage of an analog signal output from output buffer 41 subsequent to modification of the amplification factor for the analog signal with the voltage of an analog signal stored in capacitor CAP to determine whether they match or not.

When output amplifier 42 determines that the voltage of an analog signal output from output buffer 41 matches the voltage of an analog signal stored in capacitor CAP (step S1209: YES), output amplifier 42 repeats feedback control. By repeating such feedback control, semiconductor processing device 10b stably outputs an analog signal of a desired voltage from output port circuit 4b as a current source.

Next, returning to the processing of step S1204, when power supply mode register 20 determines usage as a current source for general-purpose IC 9 connected to output port circuit 4b (step S1204: YES), semiconductor processing device 10b proceeds to processing A.

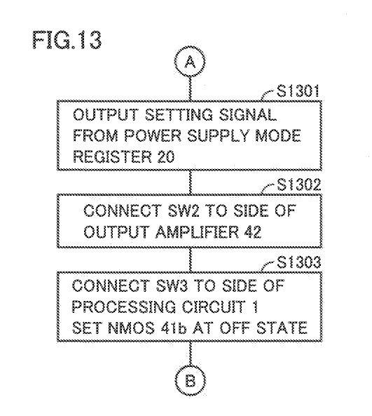

FIG. 13 is a flowchart to describe an operation of processing A of semiconductor processing device 10b according to the seventh embodiment of the present invention. First, when power supply mode register 20 determines usage as a current source for general-purpose IC 9 connected to output port circuit 4b (step S1204: YES), a setting signal is output to logic circuit A 21 (step S1301).

Then, output switch circuit 6 connects second switch element SW2 to the side of output amplifier 42 (step S1302).

Logic circuit A 21 connects second switch element SW3 connected to the gate terminal of N channel MOS transistor 41b to the side of processing circuit 1 and sets N channel MOS transistor 41b at an OFF state based on a switch signal output from output switch circuit 6 and a setting signal output from logic circuit A 21 (step S1303).

Semiconductor processing device 10b returns the processing to step S1206 (processing B) after step S1303. In other words, semiconductor processing device 10b controls the ON resistance of P channel MOS transistor 41a under the state where N channel MOS transistor 41b is OFF to output an analog signal from output buffer 41 of output port circuit 4b.

Although the description is based on providing an analog signal output from one output port circuit 4, an analog signal can be output from a plurality of output port circuits 4b by repeating a similar processing for the other output port circuits 4b. By output control circuit 3 setting in advance a desired voltage of an analog signal to be output from digital-analog conversion circuit 2 for each output port circuit 4b, the ON resistance of P channel MOS transistor 41a can be controlled for every output port circuit 4b.

Thus, semiconductor processing device 10b according to the seventh embodiment of the present invention controls the ON resistance of P channel MOS transistor 41a to output an analog signal from output buffer 41 under the state where second switch element SW3 is connected to the side of processing circuit 1 and N channel MOS transistor 41b that provides a digital signal output is at an OFF state. Therefore, semiconductor processing device 10b can have current consumption at output buffer 41 reduced when an analog signal is output from output port circuit 4b.

Since semiconductor processing device 10b controls the ON resistance of P channel MOS transistor 41a for each output port circuit 4b and outputs an analog signal from output buffer 41, an analog signal of a different voltage can be output from output buffer 41 of each output port circuit 4b.

Semiconductor processing device 10b is not limited to a configuration in which a plurality of output port circuits 4b are connected to one digital-analog conversion circuit 2. A configuration in which one output port circuit 4b is connected to one digital-analog conversion circuit 2 may be implemented. Furthermore, semiconductor processing device 10b may have a configuration in which there is a mixture of an output port circuit 4b including output amplifier 42 and an output port circuit 4b including output amplifier 48 shown in FIG. 3.

(Eighth Embodiment)

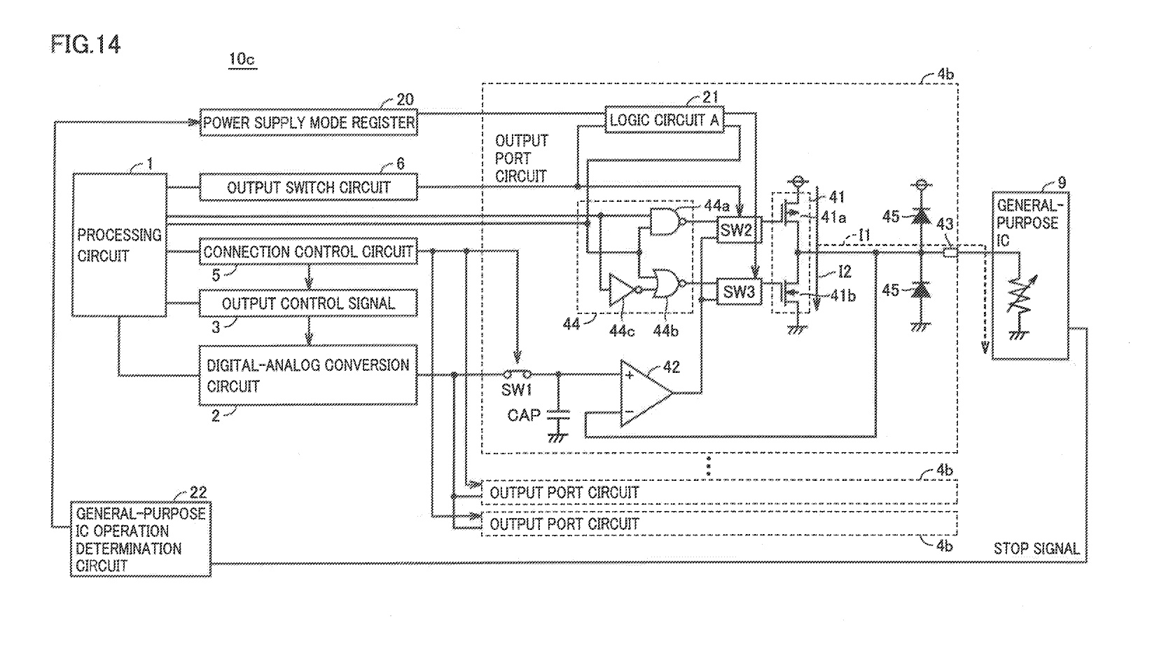

For a semiconductor processing device according to an eighth embodiment, a configuration will be described in which an analog signal of a stable voltage value can be output when a general-purpose IC supplying a current (load) achieves transition to a low power consumption state such as a standby mode, or a stopped state and the like FIG. 14 schematically represents a configuration of a semiconductor processing device according to the eighth embodiment of the present invention.

A semiconductor processing device 10c shown in FIG. 14 includes a processing circuit 1, a digital-analog conversion circuit 2, an output switch circuit 6, a plurality of output port circuits 4b, a connection control circuit 5, an output switch circuit 6, a power supply mode register 20, and a general-purpose IC operation determination circuit 22. Semiconductor processing device 10c has a configuration similar to that of semiconductor processing device 10b according to the second embodiment of the present invention except for the configuration of general-purpose IC operation determination circuit 22. Therefore, the same constituent elements have the same reference characters allotted and detailed description will not be repeated.

Semiconductor processing device 10c according to the eighth embodiment of the present invention includes general-purpose IC operation determination circuit 22 to determine the operation state of general-purpose IC 9. Specifically, when general-purpose IC 9 achieves transition to a low power consumption state or a stopped state and the like, a signal indicating a change in state (stop signal) is output to general-purpose IC operation determination circuit 22. General-purpose IC operation determination circuit 22 determines that general-purpose IC 9 has achieved transition to a low power consumption state or a stopped state and the like based on a stop signal output from general-purpose IC 9, and outputs to power supply mode register 20 a reset signal resetting the power supply mode set at power supply mode register 20.

Power supply mode register 20 outputs, when set at a power supply mode delivering current to general-purpose IC 9 connected to output port circuit 4b, a setting signal to logic circuit A 21. Logic circuit A 21 connects second switch element SW3 connected to the gate terminal of N channel MOS transistor 41b to the side of processing circuit 1 based on a switch signal output from output switch circuit 6 and a setting signal output from power supply mode register 20. Further, logic circuit A 21 provides control to output an OFF signal from NOR circuit 44b in logic circuit 44 such that N channel MOS transistor 41b attains an OFF state.

When second switch element SW2 is connected to the side of output amplifier 42 (when output buffer 41 and output amplifier 42 are connected) in output port circuit 4b, an analog signal amplified at output amplifier 42 is input to the gate terminal of P channel MOS transistor 41a. Then, output port circuit 4b controls the ON resistance of P channel MOS transistor 41a.

During operation of general-purpose IC 9, output port circuit 4b can output an analog signal from output buffer 41 to allow supply of a current to general-purpose IC 9 by controlling the ON resistance of P channel MOS transistor 41a. The voltage of the analog signal output from output port circuit 4b takes a divided value of the power supply voltage based on the ON resistance of P channel MOS transistor 41a and the ON resistance of general-purpose IC 9.

It is to be noted that, when general-purpose IC 9 achieves transition to a low power consumption state or a stopped state and the like, the voltage of the analog signal output from output port circuit 4b will be increased since the power supply voltage cannot be divided based on the ON resistance of P channel MOS transistor 41a and the ON resistance of general-purpose IC 9.

When general-purpose IC 9 achieves transition to a low power consumption state or to a stopped state and the like in semiconductor processing device 10c according to the eighth embodiment of the present invention, the power supply mode set at power supply mode register 20 is reset based on a reset signal output from general-purpose IC operation determination circuit 22. Power supply mode register 20 resets the power supply mode, and outputs to logic circuit A 21 a setting signal to set a power supply mode that supplies a reference voltage. Logic circuit A 21 connects second switch element SW3 connected to the gate terminal of N channel MOS transistor 41b to the side of output amplifier 42 based on a switch signal output from output switch circuit 6 and a setting signal output from power supply mode register 20.

When second switch elements SW2, SW3 are connected to the side of output amplifier 42 (when output buffer 41 and output amplifier 42 are connected), an analog signal amplified at output amplifier 42 is applied to the gate terminals of P channel MOS transistor 41a and N channel MOS transistor 41b to control the ON resistance of P channel MOS transistor 41a and N channel MOS transistor 41b.

When general-purpose IC 9 achieves transition to a low power consumption state or to a stopped state and the like, output port circuit 4b controls the ON resistance of P channel MOS transistor 41a and N channel MOS transistor 41b to output an analog signal from output buffer 41. Therefore, since the voltage of the analog signal output from output port circuit 4b attains a value taking into account the threshold voltage of each MOS transistor, increase in the voltage value caused by transition of general-purpose IC 9 to a low power consumption state or to a stopped state and the like can be suppressed. At output port circuit 4b, current I1 will not flow from the power supply to general-purpose IC 9 via P channel MOS transistor 41a, whereas current 12 will flow from the power supply to ground via P channel MOS transistor 41a and N channel MOS transistor 41b. Thus, when general-purpose IC 9 must receive a voltage of a level required for SRAM data storage as a low power consumption mode, such voltage supply can be implemented.

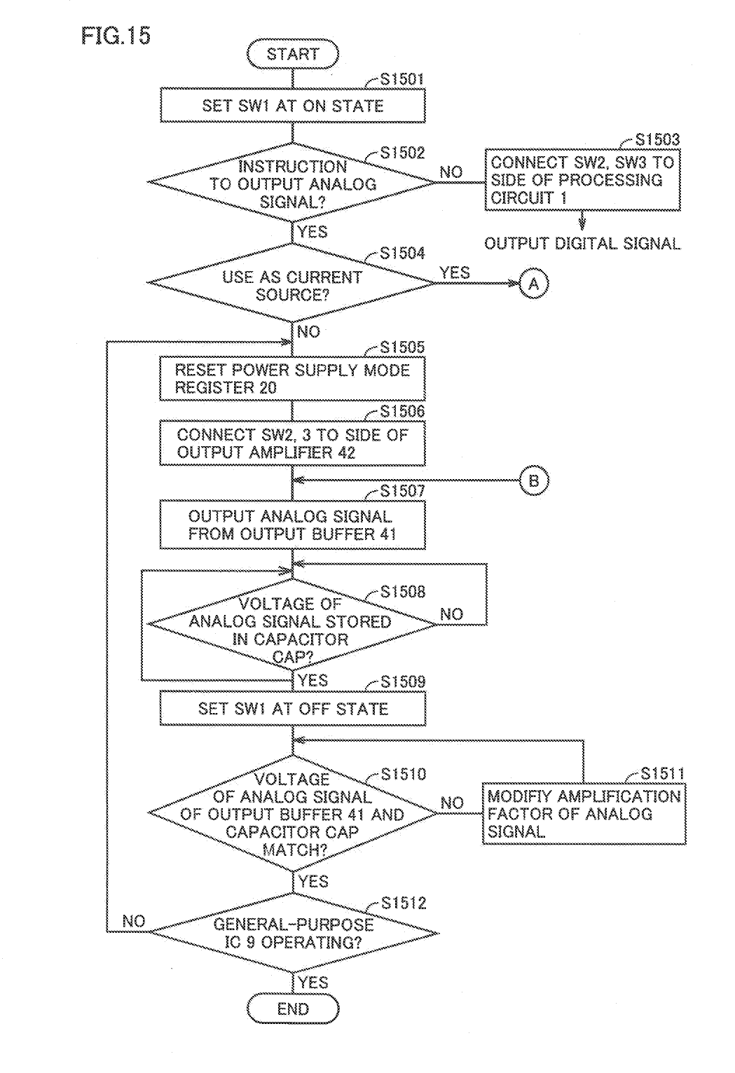

An operation of semiconductor processing device 10c according to the eighth embodiment of the present invention will be described hereinafter. FIG. 15 is a flowchart to describe an operation of semiconductor processing device 10c according to the eighth embodiment of the present invention. First, output control circuit 3 has the desired voltage of an analog signal to be output from digital-analog conversion circuit 2 set in advance. Then, connection control circuit 5 drives first switch element SW1 to an ON state (step S1501). Further, output control circuit 3 instructs digital-analog conversion circuit 2 to output an analog signal converted at digital-analog conversion circuit 2.

Then, output switch circuit 6 determines whether processing circuit 1 has instructed output of an analog signal from output port circuit 4b (step S1502). When output switch circuit 6 determines that processing circuit 1 has not instructed output of an analog signal from output port circuit 4b (step S1502: NO), output switch circuit 6 connects second switch elements SW2, SW3 to the side of processing circuit 1 (step S1503). By connecting second switch elements SW2, SW3 to the side of processing circuit 1 in semiconductor processing device 10c, a digital signal is output from output port circuit 4b.

In the case where output switch circuit 6 determines that processing circuit 1 has instructed output of an analog signal from output port circuit 4b (step S1502: YES), power supply mode register 20 determines whether to use the analog signal as a current source for general-purpose IC 9 connected to output port circuit 4b (step S1504). When power supply mode register 20 determines not to use the analog signal as a current source of general-purpose IC 9 connected to output port circuit 4b (step S1504: NO), power supply mode register 20 resets the set power supply mode (step S1505).

Output switch circuit 6 connects second switch elements SW2, SW3 to the side of output amplifier 42 (step S1506). In other words, power supply mode register 20 determines usage as a power supply delivering a reference voltage to general-purpose IC 9 connected to output port circuit 4b.

By connecting second switch elements SW2, SW3 to the side of output amplifier 42 (step S1506), semiconductor processing device 10c outputs an analog signal from output buffer 41 of output port circuit 4b (step S1507).

Then, output port circuit 4b determines whether the voltage of an analog signal output from digital-analog conversion circuit 2 is stored in capacitor CAP (step S1508).

When output port circuit 4b determines that the voltage of an analog signal output from digital-analog conversion circuit 2 is not stored in capacitor CAP (step S1508: NO), output port circuit 4b repeats the processing of step S1508.

When output port circuit 4b determines that the voltage of an analog signal output from digital-analog conversion circuit 2 is stored in capacitor CAP (step S1508: YES), connection control circuit 5 sets first switch element SW1 at an OFF state (step S1509). Output control circuit 3 instructs digital-analog conversion circuit 2 to stop the output of an analog signal converted at digital-analog conversion circuit 2.

Then, output amplifier 42 compares the voltage of an analog signal output from output buffer 41 with the voltage of an analog signal stored in capacitor CAP (the voltage of an analog signal output from digital-analog conversion circuit 2), and determines whether they match (step S1510). When output amplifier 42 determines that the voltage of an analog signal output from output buffer 41 does not match the voltage of an analog signal stored in capacitor CAP (step S1510: NO), output amplifier 42 modifies the amplification factor of an analog signal based on a difference (a compared result) between the voltage of an analog signal output from output buffer 41 and a voltage of an analog signal stored in capacitor CAP (step S1511). Following step S1511, output amplifier 42 returns to the processing of step S1510, and carries out again the comparison between the voltage of an analog signal output from output buffer 41 subsequent to modification of the amplification factor for the analog signal with the voltage of an analog signal stored in capacitor CAP to determine whether they match or not.

When output amplifier 42 determines that the voltage of an analog signal output from output buffer 41 matches the voltage of an analog signal stored in capacitor CAP (step S1510: YES), semiconductor processing device 10c repeats feedback control (step S1510). An analog signal of a desired voltage is stably output from output port circuit 4b as a current source.

General-purpose IC operation determination circuit 22 determines whether general-purpose IC 9 is operating or not (step S1512). When general-purpose IC operation determination circuit 22 determines that general-purpose IC 9 is operating (step S1512: YES), semiconductor processing device 10c continuously outputs an analog signal of a desired voltage from output port circuit 4b as a current source.

When general-purpose IC operation determination circuit 22 determines that general-purpose IC 9 has achieved transition to a low power consumption state or to a stopped state and the like (step S1512: NO), a reset signal is output to power supply mode register 20 to reset the power supply mode set at power supply mode register 20 (step S1505). Then, output port circuit 4b is set at a power supply mode delivering the reference voltage, and second switch elements SW2, SW3 are connected to the side of output amplifier 42. Returning to the processing of step S1504, when power supply mode register 20 determines usage as a current source of general-purpose IC 9 connected to output port circuit 4b (step S1504: YES), semiconductor processing device 10c proceeds to processing A. Processing A is similar to the processing described with reference to FIG. 13 in the seventh embodiment. Therefore, detailed description will not be repeated.

Although the description is based on the case where the connected load achieves transition to a low power consumption state or to a stopped state and the like for one output port circuit 4b, a similar processing can be applied to other output port circuits 4b. By setting power supply mode register 20 to cause output of a reset signal for each output port circuit 4b, the stoppage of a load connected to each output port circuit 4b can be accommodated.

As described above, semiconductor processing device 10c according to the eighth embodiment of the present invention resets the power supply mode set at power supply mode register 20 when general-purpose IC 9 stops. Therefore, the voltage of an analog signal output from output port circuit 4b attains a level taking into account the threshold voltage of each MOS transistor. Increase in the voltage value caused by stoppage of general-purpose IC 9 can be suppressed.

Since semiconductor processing device 10c controls the ON resistance of P channel MOS transistor 41a for each output port circuit 4b to output an analog signal from output buffer 41, an analog signal of a different voltage can be output from output buffer 41 of each output port circuit 4b.

Semiconductor processing device 10c is not limited to a configuration in which a plurality of output port circuits 4b are connected to one digital-analog conversion circuit 2. A configuration in which one output port circuit 4b is connected to one digital-analog conversion circuit 2 may be implemented. Furthermore, semiconductor processing device 10c may have a configuration in which there is a mixture of an output port circuit 4b including output amplifier 42 and an output port circuit 4b including output amplifier 48 shown in FIG. 3.

(Ninth Embodiment)

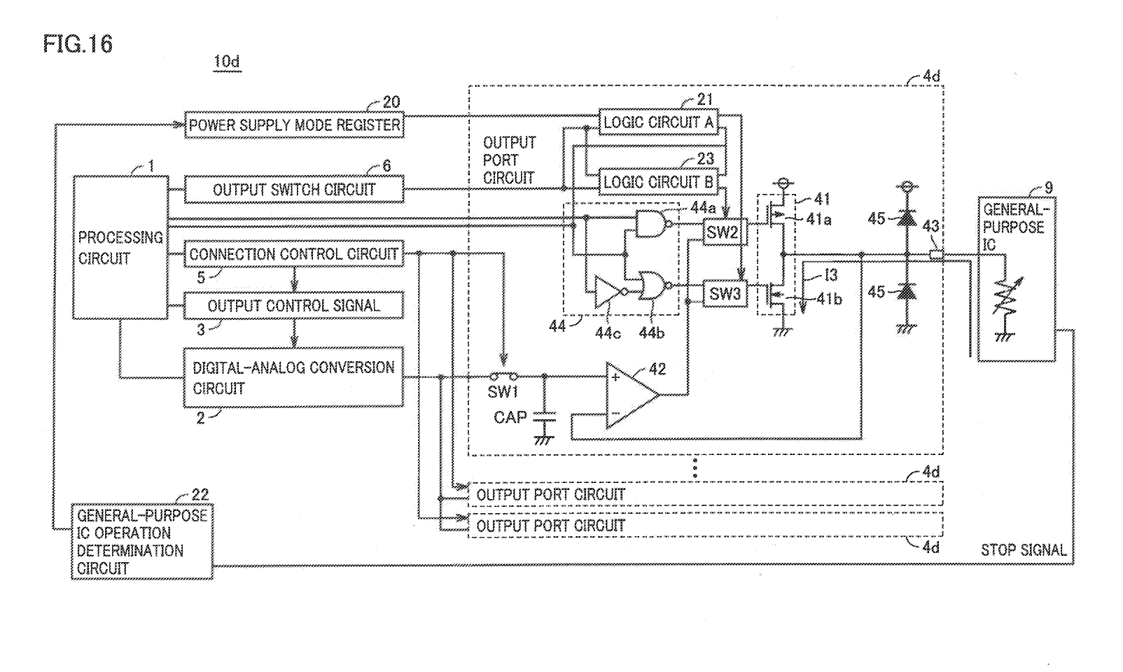

For a semiconductor processing device according to a ninth embodiment, a configuration will be described in which a power supply cutoff mode can be set for a general-purpose IC (load) when the general-purpose IC (load) to which a current is supplied stops. FIG. 16 is a schematic diagram representing a configuration of a semiconductor processing device according to the ninth embodiment of the present invention.

A semiconductor processing device 10d of FIG. 16 includes a processing circuit 1, a digital-analog conversion circuit 2, an output control circuit 3, a plurality of output port circuits 4d, a connection control circuit 5, an output switch circuit 6, a power supply mode register 20, and a general-purpose IC operation determination circuit 22. Semiconductor processing device 10d has a configuration similar to that of semiconductor processing device 10c according to the eighth embodiment of the present invention, except for the configuration of output port circuit 4d. Therefore, the same constituent elements have the same reference characters allotted and detailed description will not be repeated.

Semiconductor processing device 10d according to the ninth embodiment of the present invention includes a general-purpose IC operation determination circuit 22 to determine the operation state of general-purpose IC 9. Output port circuit 4d differs from output port circuit 4b shown in FIG. 14 in that second switch element SW2 and second switch element SW3 are connected to a logic circuit B 23 and a logic circuit A 21, respectively. Therefore, power supply mode register 20 outputs a setting signal to logic circuit B 23 and logic circuit A 21 based on a reset signal output from general-purpose IC operation determination circuit 22. Logic circuit B 23 and logic circuit A 21 switch the connection of second switch elements SW2, SW3 to the side of processing circuit 1 or to the side of output amplifier 42 based on the setting signal.

Specifically, the case where power supply mode register 20 is set at a power supply mode delivering a current to general-purpose IC 9 connected to output port circuit 4d and in an operating state will be described. Logic circuit B 23 connects second switch element SW2 connected to the gate terminal of P channel MOS transistor 41a to the side of output amplifier 42 based on a switch signal output from output switch circuit 6 and a setting signal output from power supply mode register 20.

Logic circuit A 21 connects second switch element SW3 connected to the gate terminal of N channel MOS transistor 41b to the side of processing circuit 1 based on a switch signal output from output switch circuit 6 and a setting signal output from power supply mode register 20. Further, logic circuit A 21 provides control to output an OFF signal from NOR circuit 44b in logic circuit 44 such that N channel MOS transistor 41b attains an OFF state.

When second switch element SW2 is connected to the side of output amplifier 42 (when output buffer 41 and output amplifier 42 are connected) in output port circuit 4d , the analog signal amplified at output amplifier 42 is input to the gate terminal of P channel MOS transistor 41 a. Then, output port circuit 4d controls the ON resistance of P channel MOS transistor 41a.

By controlling the ON resistance of P channel MOS transistor 41a, output port circuit 4d can output an analog signal from output buffer 41 to supply a current to general-purpose IC 9. The voltage of an analog signal output from output port circuit 4d takes a divided value of the power supply voltage based on the ON resistance of P channel MOS transistor 41a and the ON resistance of general-purpose IC 9.

It is to be noted that, when general-purpose IC 9 achieves a stopped state, the voltage of the analog signal output from output port circuit 4b will be increased since the power supply voltage cannot be divided based on the ON resistance of P channel MOS transistor 41a and the ON resistance of general-purpose IC 9.

When general-purpose IC 9 stops at semiconductor processing device 10d according to the ninth embodiment of the present invention, the power supply mode set at power supply mode register 20 is reset based on a reset signal output from general-purpose IC operation determination circuit 22, and a setting signal setting the power supply cutoff mode is output to logic circuit B 23 and logic circuit A 21.

Logic circuit B 23 connects second switch element SW2 connected to the gate terminal of P channel MOS transistor 41a to the side of processing circuit 1 based on a switch signal output from output switch circuit 6 and a setting signal output from power supply mode register 20. Further, logic circuit B 23 provides control to output an OFF signal from NAND circuit 44a of logic circuit 44 such that P channel MOS transistor 41a attains an OFF state.

Logic circuit A 21 connects second switch element SW3 connected to the gate terminal of N channel MOS transistor 41b to the side of processing circuit 1 based on a switch signal output from output switch circuit 6 and a setting signal output from power supply mode register 20. Furthermore, logic circuit A 21 provides control to output an ON signal from NOR circuit 44b in logic circuit 44 such that N channel MOS transistor 41b attains ON state.

By P channel MOS transistor 41a attaining an OFF state and N channel MOS transistor 41b attaining an ON state, the voltage value of an analog signal output from output buffer 41 can be set at 0 V, allowing a power supply cut off state for general-purpose IC 9 to be realized. Output port circuit 4d has current 13 flow from general-purpose IC 9 to the ground potential via N channel MOS transistor 41b.

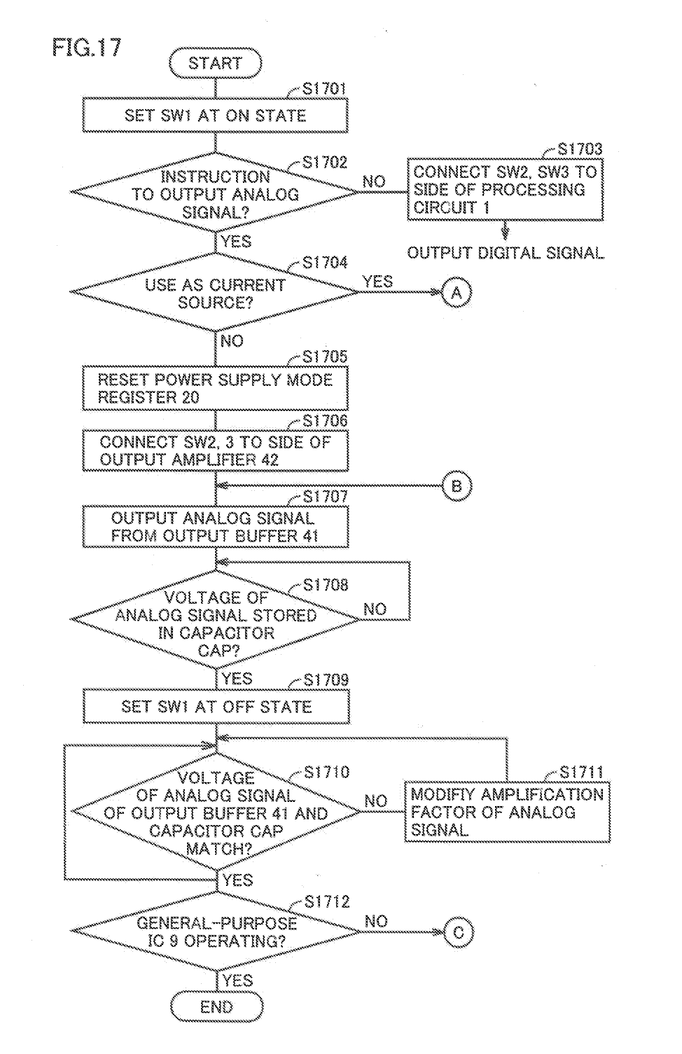

An operation of semiconductor processing device 10d according to the ninth embodiment of the present invention will be described hereinafter. FIG. 17 is a flowchart to describe an operation of semiconductor processing device 10d according to the ninth embodiment of the present invention. First, output control circuit 3 has the desired voltage of an analog signal to be output from digital-analog conversion circuit 2 set in advance. Then, connection control circuit 5 drives first switch element SW1 to an ON state (step S1701). Further, output control circuit 3 instructs digital-analog conversion circuit 2 to output an analog signal converted at digital-analog conversion circuit 2.

Then, output switch circuit 6 determines whether processing circuit 1 has instructed output of an analog signal from output port circuit 4d (step S1702). When output switch circuit 6 determines that processing circuit 1 has not instructed output of an analog signal from output port circuit 4d (step S1702: NO), output switch circuit 6 connects second switch elements SW2, SW3 to the side of processing circuit 1 (step S1703). By connecting second switch elements SW2, SW3 to the side of processing circuit 1 in semiconductor processing device 10d, a digital signal is output from output port circuit 4d.

In the case where output switch circuit 6 determines that processing circuit 1 has instructed output of an analog signal from output port circuit 4d (step S1702: YES), power supply mode register 20 determines whether to use the analog signal as a current source for general-purpose IC 9 connected to output port circuit 4d (step S1704). When power supply mode register 20 determines not to use the analog signal as a current source of general-purpose IC 9 connected to output port circuit 4d (step S1704: NO), power supply mode register 20 resets the set power supply mode(step S1705).

Output switch circuit 6 connects second switch elements SW2, SW3 to the side of output amplifier 42 (step S1706) In other words, power supply mode register 20 determines usage as a power supply delivering a reference voltage to general-purpose IC 9 connected to output port circuit 4d.

By connecting second switch elements SW2, SW3 to the side of output amplifier 42 (step S1706), semiconductor processing device 10d outputs an analog signal from output buffer 41 of output port circuit 4d (step S1707).

Then, output port circuit 4d determines whether the voltage of an analog signal output from digital-analog conversion circuit 2 is stored in capacitor CAP (step S1708). When output port circuit 4d determines that the voltage of an analog signal output from digital-analog conversion circuit 2 is not stored in capacitor CAP (step S1708:NO), output port circuit 4d repeats the processing of step S1708.

When output port circuit 4d determines that the voltage of an analog signal output from digital-analog conversion circuit 2 is stored in capacitor CAP (step S1708: YES), connection control circuit 5 sets first switch element SW1 at an OFF state (step S1709). Output control circuit 3 instructs digital-analog conversion circuit 2 to stop the output of an analog signal converted at digital-analog conversion circuit 2.

Then, output amplifier 42 compares the voltage of an analog signal output from output buffer 41 with the voltage of an analog signal stored in capacitor CAP (the voltage of an analog signal output from digital-analog conversion circuit 2), and determines whether they match (step S1710). When output amplifier 42 determines that the voltage of an analog signal output from output buffer 41 does not match the voltage of an analog signal stored in capacitor CAP (step S1710: NO), output amplifier 42 modifies the amplification factor of an analog signal based on a difference (a compared result) between the voltage of an analog signal output from output buffer 41 and a voltage of an analog signal stored in capacitor CAP (step S1711). Following step S1711, output amplifier 42 returns to the processing of step S1710, and carries out again the comparison between the voltage of an analog signal output from output buffer 41 subsequent to modification of the amplification factor for the analog signal with the voltage of an analog signal stored in capacitor CAP to determine whether they match or not.

When output amplifier 42 determines that the voltage of an analog signal output from output buffer 41 matches the voltage of an analog signal stored in capacitor CAP (step S1710: YES), semiconductor processing device 10d repeats feedback control (step S1710). An analog signal of a desired voltage is stably output from output port circuit 4d as a current source.

General-purpose IC operation determination circuit 22 determines whether general-purpose IC 9 is operating or not (step S1712). When general-purpose IC operation determination circuit 22 determines that general-purpose IC 9 is operating (step S1712: YES), semiconductor processing device 10d continuously outputs an analog signal of a desired voltage from output port circuit 4d as a current source.

When general-purpose IC operation determination circuit 22 determines that general-purpose IC 9 is not operating (stopped) (step S1712: NO), semiconductor processing device 10d proceeds to processing C.

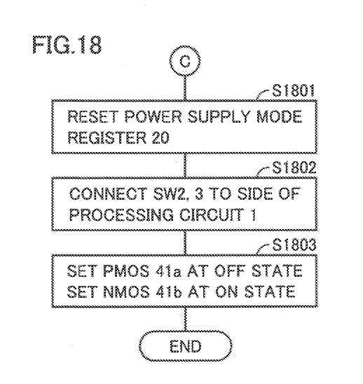

FIG. 18 is a flowchart to describe an operation of processing C in semiconductor processing device 10d according to the ninth embodiment of the present invention. First, when general-purpose IC operation determination circuit 22 determines that general-purpose IC 9 is not operating (stopped) (step S1712: NO), power supply mode register 20 resets the set power supply mode (step S1801).

Then, logic circuit B 23 and logic circuit A 21 connect second switch elements SW2, SW3 to the side of processing circuit 1 based on a switch signal output from output switch circuit 6 and a setting signal output from power supply mode register 20 (step S1802).

Furthermore, logic circuit B 23 and logic circuit A 21 provide control via logic circuit 44 such that P channel MOS transistor 41a attains an OFF state and N channel MOS transistor 41b attains an ON state (step S1803).

Returning to the processing of step S1704, when power supply mode register 20 determines usage as a current source for general-purpose IC 9 connected to output port circuit 4d (step S 1704: YES), semiconductor processing device 10d proceeds to processing A. Processing A is similar to the processing described with reference to FIG. 13 of the seventh embodiment. Therefore, detailed description will not be repeated.

Although the description is based on the processing corresponding to the case where the connected load stops for one output port circuit 4d, a similar processing can be applied to the other output port circuits 4d. By setting power supply mode register 20 to cause output of a reset signal for each output port circuit 4b, the stoppage of a load connected to each output port circuit 4b can be accommodated.

Thus, a power supply cut off mode can be set when general-purpose IC 9 stops at semiconductor processing device 10d according to the ninth embodiment of the present invention. Since leakage current from output port circuit 4d towards general-purpose IC 9 can be cut off, the overall current consumption at the device can be reduced.

Semiconductor processing device 10d is not limited to a configuration in which a plurality of output port circuits 4d are connected to one digital-analog conversion circuit 2. A configuration in which one output port circuit 4d is connected to one digital-analog conversion circuit 2 may be implemented. Furthermore, semiconductor processing device 10d may have a configuration in which there is a mixture of an output port circuit 4d including output amplifier 42 and an output port circuit 4d including output amplifier 48 shown in FIG. 3.

It is to be understood that the embodiments disclosed herein are only by way of example, and not to be taken by way of limitation. The scope of the present invention is not limited by the description above, but rather by the terms of the appended claims, and is intended to include any modifications within the scope and meaning equivalent to the terms of the claims.

### REFERENCE SIGNS LIST

1 processing circuit; 2 digital-analog conversion circuit; 3 output control circuit; 4, 4a, 4b, 4d output port circuit; 5, 50 connection control circuit; 6 output switch circuit; 7 serial input/output port; 8 peripheral function circuit; 9 general-purpose IC; 10, 10a, 10b, 10c, 10d, 11, 12, 13 semiconductor processing device; 20 power supply mode register; 21 logic circuit A; 22 general-purpose IC operation determination circuit; 23 logic circuit B; 31, 49, 52 register; 41 output buffer; 42, 48 output amplifier; 43 output port; 44 logic circuit; 45 protection diode; 51 counter; 60 memory circuit; 61, 71 general-purpose IC; 70 external connection circuit; 80 communication circuit; 90 sensor circuit; 91 sensor element; 100

1. A semiconductor processing device comprising:
a processing circuit,
a digital-analog conversion circuit converting a digital signal output from said processing circuit into an analog signal,
an output control circuit controlling output of a analog signal converted at said digital-analog conversion circuit,
at least one output port circuit for providing a digital signal output from said processing circuit and an analog signal output from said digital-analog conversion circuit to an external source,
a connection control circuit controlling connection of said digital-analog conversion circuit and said output port circuit, and
an output switch circuit switching output from said output port circuit between a digital signal and an analog signal to an external source,
said output port circuit including
an output buffer having a transistor circuit to output a digital signal by switching between an ON state and an OFF state of the transistor circuit,
an output amplifier amplifying an analog signal output from said digital-analog conversion circuit,
a first switch element provided between said digital-analog conversion circuit and said output amplifier to switch between connection and disconnection of said digital-analog conversion circuit and said output amplifier based on a control signal output from said connection control circuit, and
a second switch element connected to a gate terminal of said transistor circuit, and switching between connection to a side of said processing circuit and connection to a side of said output amplifier based on a switch signal output from said output switch circuit,
said output port circuit controlling, when said second switch element is connected to the side of said output amplifier, the ON resistance of said transistor circuit based on a signal amplified at said output amplifier to output an analog signal from said output buffer.

2. The semiconductor processing device according to claim 1, wherein said output amplifier modifies an amplification factor of an analog signal based on a comparison result between a voltage of an analog signal output from said output buffer and a voltage of an analog signal output from said digital-analog conversion circuit.

3. The semiconductor processing device according to claim 1, wherein said output port circuit includes a capacitor storing a voltage of an analog signal output from said digital-analog conversion circuit when said digital-analog conversion circuit and said output amplifier are connected by said first switch element.

4. The semiconductor processing device according to claim 1, wherein said transistor circuit of said output buffer is constituted of a CMOS circuit having a P channel MOS transistor and an N channel MOS transistor connected in series.

5. The semiconductor processing device according to claim 4, wherein said output amplifier outputs a different analog signal to said P channel MOS transistor of said output buffer and said N channel MOS transistor of said output buffer.

6. The semiconductor processing device according to claim 1, wherein
said connection control circuit includes a counter sequentially selected a port number set corresponding to each of a plurality of said output port circuits,
said output control circuit sets in advance a voltage of an analog signal converted at said digital-analog conversion circuit corresponding to the port number selected at said counter, and
said connection control circuit sets said first switch element of said output port circuit corresponding to the port number selected at said counter at an ON state.

7. A semiconductor processing system comprising:
the semiconductor processing device defined in claim 1, and
at least one circuit connected to said output port circuit of said semiconductor processing device, driven by an analog signal output from said output port circuit.

8. The semiconductor processing device according to claim 1, wherein
said transistor circuit of said output buffer is constituted of a CMOS circuit including a P channel MOS transistor and an N channel MOS transistor connected in series between a power supply and ground,
when said second switch element is connected to only a gate terminal of said P channel MOS transistor, and
an analog signal is output from said output port circuit to an external source to supply a current to a load connected to said output port circuit by the analog signal,
said N channel MOS transistor is set at an OFF state, and
said P channel MOS transistor has an ON resistance controlled based on a signal amplified at said output amplifier.

9. The semiconductor processing device according to claim 1, wherein
said transistor circuit of said output buffer is constituted of a CMOS circuit including a P channel MOS transistor and an N channel MOS transistor connected in series between a power supply and ground,
when said second switch element is connected to each gate terminal of said P channel MOS transistor and said N channel MOS transistor, and
an analog signal is output from said output port circuit to an external source to supply a current to a load connected to said output port circuit by the analog signal,
said N channel MOS transistor is set at an OFF state, and
said P channel MOS transistor has an ON resistance controlled based on a signal amplified at said output amplifier.

10. The semiconductor processing device according to claim 9, further comprising a power supply mode register providing to said output port circuit a setting signal for setting said output port circuit at a power supply mode delivering a current to said load connected to said output port circuit,
wherein said output port circuit further includes a first logic circuit connecting said second switch element connected to the gate terminal of said N channel MOS transistor to a side of said processing circuit, and controlling said N channel MOS transistor to take an OFF state, based on said switch signal output from said output switch circuit and said setting signal output from said power supply mode register.

11. The semiconductor processing device according to claim 10, further comprising a load determination circuit determining an operation of said load based on a signal output from said load,
wherein said load determination circuit outputs a reset signal to said power supply mode register to reset the power supply mode set at said power supply mode register when a determination is made that an operation of said load is stopped.

12. The semiconductor processing device according to claim 10, further comprising a load determination circuit determining an operation of said load based on a signal output from said load, wherein
said load determination circuit outputs a reset signal to said power supply mode register to set said power supply mode register at a power supply cutoff mode when a determination is made that an operation of said load is stopped, and
said output port circuit further includes a second logic circuit connecting said second switch element connected to the gate terminal of said P channel MOS transistor to a side of said processing circuit to set said P channel MOS transistor at an OFF state, based on said switch signal output from said output switch circuit and said setting signal output from said power supply mode register.
